(19) United States
(12) Patent Application Publication
(10) Pub. No.: US 2009/0258493 A1
(43) Pub. Date: Oct. 15, 2009

(54) SEMICONDUCTOR DEVICE MANUFACTURING METHOD

(76) Inventors: Yukiteru MATSUI, Kanagawa (JP); Hajime EDA, Kanagawa (JP); Takatoshi ONO, Kanagawa (JP); Satoko Seta, Tokyo (JP); Yoshikuni TATEYAMA, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/403,979

(22) Filed: Mar. 13, 2009

(30) Foreign Application Priority Data
Mar. 31, 2008 (JP) 2008-093252
Feb. 23, 2009 (JP) 2009-039548

(51) Int. Cl. H01L 21/306

(52) U.S. Cl. 438/693; 257/E21.23

(57) ABSTRACT

A substance to be polished made of a silicon oxide film formed on a semiconductor substrate is chemically and mechanically polished and planarized by bringing the substance to be polished into contact with a polishing pad having a modulus of elasticity within a range of 400 to 600 megapascals and by relatively sliding the substance to be polished and the polishing pad, in a condition that a polishing pressure is within a range of 50 to 200 hectopascals and that a rotation number of the polishing pad is within a range of 10 to 80 rpm, and in a state that a polishing slurry containing cerium oxide particles and an anionic surfactant is supplied to the polishing pad.

### CROSS-REFERENCE TO RELATED APPLICATIONS

This application is based upon and claims the benefit of priority from the prior Japanese Patent Application No. 2008-093252, filed on Mar. 31, 2008; and Japanese Patent Application No. 2009-039548, filed on Feb. 23, 2009, the entire contents of both of which are incorporated herein by reference.

### BACKGROUND OF THE INVENTION

1. Field of the Invention

The present invention relates to a semiconductor device manufacturing method.

2. Description of the Related Art

Recently, a chemical mechanical polishing method (CMP) has been mainly used as a planarization technique used for semiconductor device manufacturing processes. Particularly, a CMP process performed on a silicon oxide film is used to form a shallow trench isolation (STI) and for a pre-metal dielectric (PMD) planarization and the like. The CMP process is essential for device manufacturing, and is also very important for semiconductor device manufacturing processes.

Conventionally, degradation of flatness such as dishing generated in a CMP process has been avoided by a pattern design. However, when a pattern has a large area of convexities, the pattern design alone cannot avoid the degradation of flatness such as dishing. Therefore, a technique of not generating degradation of flatness, such as dishing in the planarization of a large area of convexities, has been demanded.

From the viewpoint of preventing the occurrence of dishing, for example, Japanese Patent No. 3278532 proposes a technique of adding an organic compound of a molecular weight equal to or higher than 100 having at least one hydrophilic group in a polishing liquid.

However, when a region having a large area of convexities is tried to be planarized by the conventional technique, a high pressure is applied to only an end of each convexity due to elastic deformation of a polishing pad, and the applied pressure decreases toward the center of the convexity. Consequently, flatness is degraded without performing uniform polishing. This phenomenon becomes conspicuous in a high density pattern having a large area equal to or larger than 2 mm×2 mm with a convexity coverage equal to or larger than 80%.

### BRIEF SUMMARY OF THE INVENTION

According to one aspect of the present invention, a semiconductor device manufacturing method includes bringing a substance to be polished made of a silicon oxide film formed on a semiconductor substrate into contact with a polishing pad, in a state that a polishing slurry containing cerium oxide particles and an anionic surfactant is supplied to the polishing pad having a modulus of elasticity within a range of 400 to 600 megapascals arranged above a polishing table, and in a condition that a polishing pressure applied to the substance to be polished is within a range of 50 to 200 hectopascals and that a rotation number of the polishing pad is within a range of 10 to 80 revolutions per minute (rpm); and sliding the substance to be polished and the polishing pad relatively, thereby chemically and mechanically polishing and planarizing the substance to be polished.

According to another aspect of the present invention, a semiconductor device manufacturing method includes sliding a substance to be polished made of a silicon oxide film formed on a semiconductor substrate with a polishing pad relatively, in a state that a polishing slurry containing resin particles having a cationic surface functional group, cerium oxide particles, and an anionic surfactant is supplied to the polishing pad arranged above a polishing table, thereby chemically and mechanically polishing and planarizing the substance to be polished.

According to still another aspect of the present invention, a semiconductor device manufacturing method includes bringing a substance to be polished made of a silicon oxide film formed on a semiconductor substrate into contact with a polishing pad, in a state that a polishing slurry containing resin particles having a cationic surface function group, cerium oxide particles, and an anionic surfactant is supplied to the polishing pad having a modulus of elasticity within a range of 400 to 600 megapascals arranged above a polishing table, and in a condition that a polishing pressure applied to the substance to be polished is within a range of 50 to 200 hectopascals and that a rotation number of the polishing pad is within a range of 10 to 80 rpm; and sliding the substance to be polished and the polishing pad relatively, thereby chemically and mechanically polishing and planarizing the substance to be polished.

### BRIEF DESCRIPTION OF THE DRAWINGS

FIG. 1 is a cross-sectional view of an example of a processing target of a planarizing process using a semiconductor device manufacturing method according to a first embodiment of the present invention;

FIG. 2 is a schematic diagram of an overall configuration of a polishing device that performs a planarizing process on a silicon oxide film using the semiconductor device manufacturing method according to the first embodiment;

FIG. 3 is a schematic diagram for explaining a conventional CMP process performed on a silicon oxide film;

FIG. 4 is a schematic diagram for explaining a CMP process performed on a silicon oxide film by a polishing pad of a high modulus of elasticity according to the first embodiment;

FIG. 5 is a schematic diagram for explaining an effect obtained by containing resin particles having a cationic surface functional group in a polishing slurry, according to another embodiment of the present invention;

FIG. 6 is a schematic diagram for explaining a state that cerium oxide particles are fixed to a polishing pad by arranging such that the polishing slurry contain the resin particles having a cationic surface functional group, according to the another embodiment;

FIG. 7 is a schematic diagram for explaining a CMP process when a polishing pad of a high modulus of elasticity is combined with the polishing slurry containing resin particles having a cationic surface functional group;

FIG. 8 is a schematic diagram for explaining a sample according to the first embodiment;

FIG. 9 is a schematic diagram for explaining another sample according to the first embodiment;

FIG. 10 is a diagram of CMP processing conditions of examples in the first embodiment;

FIG. 11 is a diagram of CMP processing conditions of comparative examples in the first embodiment;

FIG. 12 is a diagram of CMP processing conditions of other examples in the first embodiment;

FIG. 13 is a diagram of CMP processing conditions of other comparative example in the first embodiment;

FIG. 14 is a diagram of CMP processing results of examples and comparative examples of a sample of a pattern A in the first embodiment;

FIG. 15A to FIG. 15H are diagrams of CMP processing results of examples and comparative examples of a sample of a pattern B in the first embodiment;

FIG. 16A to FIG. 16C are diagrams of CMP processing results of the examples and comparative examples of the sample of the pattern B in the first embodiment;

FIG. 17 is a schematic diagram of a state of a polished surface after a CMP process in an example and a comparative example in the first embodiment;

FIG. 18 is a diagram of a relationship between a content of anionic surfactants in the polishing slurry and an agglomerated particle diameter of cerium oxide, in an example of the first embodiment;

FIG. 19 is a diagram of characteristics of a change of a ζ potential when a temperature of the polishing slurry is changed;

FIG. 20 is a schematic diagram of an adsorption state of cerium oxide particles and anionic surfactants when the polishing slurry has a high temperature;

FIG. 21 is a schematic diagram of an adsorption state of cerium oxide particles and anionic surfactants when the polishing slurry has a lower temperature;

FIG. 22 is a diagram of an example of characteristics of a change of a relationship between a polishing load and polishing speed due to a polishing slurry temperature in the CMP process performed on a silicon oxide film;

FIG. 23 is a schematic diagram of a concavity protection state when a conventional polishing slurry containing cerium oxide particles and anionic surfactants is used;

FIG. 24 is a schematic diagram of a concavity protection state when a polishing slurry containing the cerium oxide particles, the anionic surfactants, and the resin particles having a cationic surface functional group is used;

FIG. 25 is a schematic diagram for explaining a state between a silicon oxide film and a polishing pad in a CMP process using a polishing slurry having a large content of cerium oxide particles;

FIG. 26 is a schematic diagram for explaining a state between the silicon oxide film and the polishing pad in a CMP process using a polishing slurry having a small content of the cerium oxide particles;

FIG. 27 is a schematic diagram of an overall configuration of a polishing device that performs the CMP process on the silicon oxide film using semiconductor device manufacturing method according to a second embodiment of the present invention;

FIG. 28 is a diagram of an example of surface temperature characteristics of a polishing pad in the CMP process performed on a silicon oxide film using a polishing slurry containing the cerium oxide particles, the anionic surfactants, and the resin particles having a cationic surface functional group;

FIG. 29 is a schematic diagram for explaining a sample according to the second embodiment;

FIGS. 30A and 30B are diagrams of CMP processing conditions in examples and a comparative example in the second embodiment;

FIG. 31 is a schematic diagram for explaining a sample according to a third embodiment of the present invention;

FIG. 32 is a diagram of an example of characteristics of a relationship between an indentation depth and a modulus of elasticity of a polishing pad according to the third embodiment;

FIG. 33 is a schematic diagram for explaining another sample according to the third embodiment;

FIG. 34 is a diagram of a scratch occurrence state and a global flatness in an example and comparative examples in the third embodiment; and

FIG. 35 is a diagram of a global flatness in another example and comparative example in the third embodiment.

### DETAILED DESCRIPTION OF THE INVENTION

Exemplary embodiments of a semiconductor device manufacturing method according to the present invention will be explained below in detail with reference to the accompanying drawings. The present invention is not limited to the following embodiments and various modifications are also included therein within the scope of the invention.

### First Embodiment

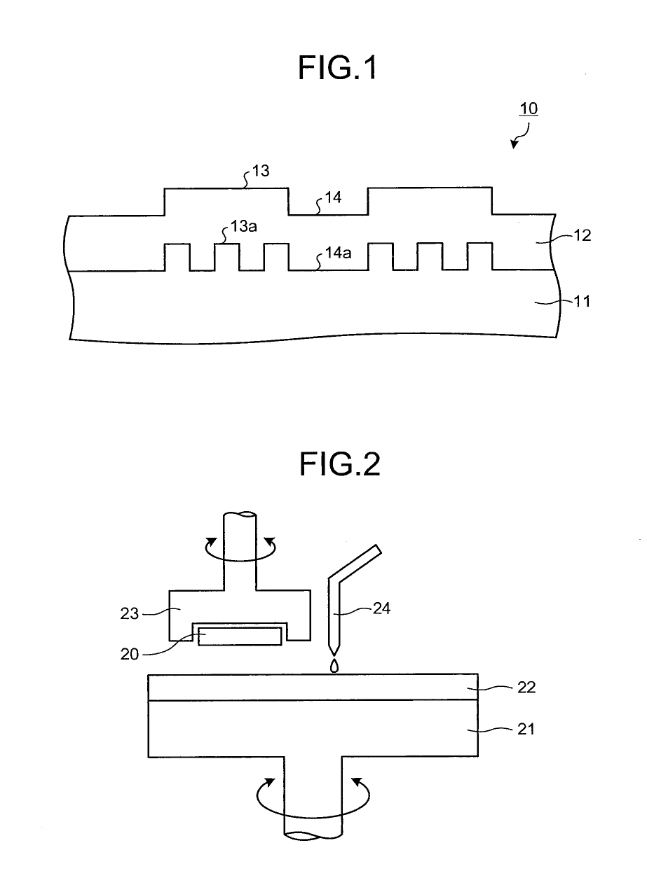

FIG. 1 is a cross-sectional view of a semiconductor substrate 10 as an example to which a planarizing process is applied by the CMP using a semiconductor device manufacturing method according to a first embodiment of the present invention. The semiconductor substrate 10 has a silicon oxide film 12 formed as an insulation film on a silicon substrate 11 having a region of 2 mm×2 mm or more formed with a fine pattern including convexities 13a and concavities 14a, with a convexity coverage (proportion of convexities) equal to or larger than 80%. While the silicon substrate 11 is suitably formed with various device portions such as diffusion layers and gates of transistors, these portions are omitted from FIG. 1. The silicon oxide film 12 is formed with convexities 13 and concavities 14. When a fine pattern is formed in the region of 2 mm×2 mm or more with the convexity coverage equal to or larger than 80%, this fine pattern is blocked at the time of forming the silicon oxide film 12, thereby forming a large area of the convexities 13. A semiconductor device manufacturing method capable of performing a planarizing process of forming high flatness of the convexities 13 is explained below.

FIG. 2 is a schematic diagram of an overall configuration of a polishing device that performs a planarizing process on the silicon oxide film 12 of the semiconductor substrate 10 using the semiconductor device manufacturing method according to the first embodiment. This polishing device includes a rotatable polishing table 21, a polishing pad 22 made of a polyurethane resin and adhered to an upper surface of the polishing table 21, a rotatable vacuum chuck holder 23 arranged above the polishing table 21, and a polishing-liquid supply pipe 24 connected to a polishing liquid tank and having a discharge opening extended to near the polishing pad 22. A sample 20 to be polished is vacuum-chucked to the vacuum chuck holder 23 so that a polished surface faces the polishing pad 22. The polishing-liquid supply pipe 24 includes a unit (not shown) that controls a supply amount of a polishing liquid.

Next, a method of performing the planarizing process on the silicon oxide film 12 of the semiconductor substrate 10 by the CMP by the polishing device is explained.

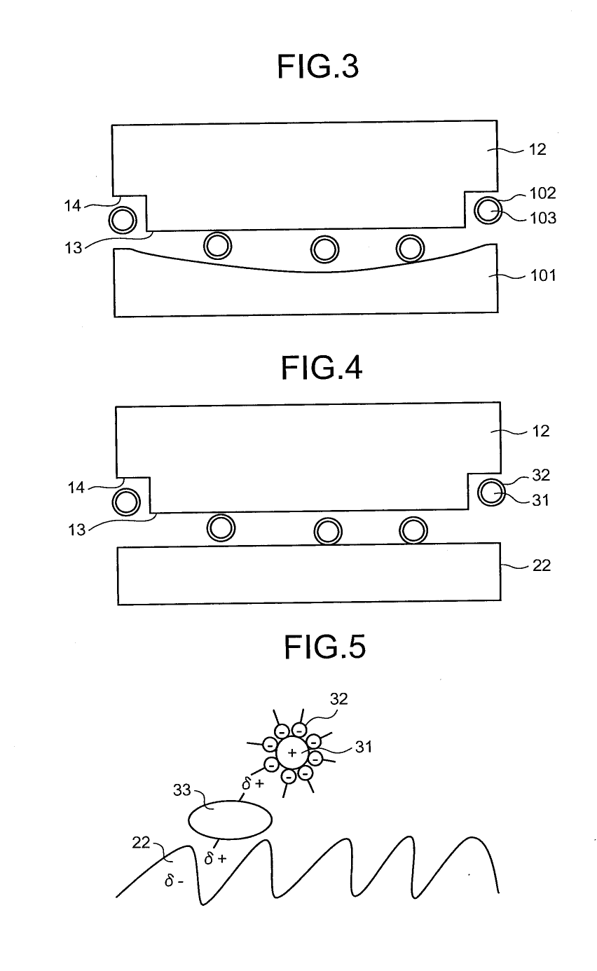

FIG. 3 is a schematic diagram for explaining a conventional CMP process performed on a silicon oxide film. As shown in FIG. 3, in performing the CMP process on the silicon oxide film 12, a polishing slurry containing cerium oxide particles 103 and anionic surfactants 102 is supplied onto a polishing pad 101. Polycarboxylic acid or its salt can be used for the anionic surfactant 102. The anionic surfactants 102 are coated on the cerium oxide particles 103 as abrasive grains, between the polishing pad 101 and the silicon oxide film 12.

Conventionally, the polishing pad 101 generally used to perform the CMP process on the silicon oxide film 12 has a small modulus of elasticity such as about 300 megapascals, and is easily elastically deformed at the CMP processing time. Conventionally, a polishing pressure generally used to perform the CMP process on a hard material such as the silicon oxide film 12 is about 30 to 700 hectopascals. To improve production efficiency, a high pressure in this range is used. Conventionally, a rotation number of the polishing pad 101 generally used to perform the CMP process on a hard material such as the silicon oxide film 12 is about 5 to 200 revolutions per minute (rpm). To improve production efficiency, a high rotation number in this range is used. That is, the silicon oxide film 12 is a hard material as compared with a material such as copper (Cu), and is not easily polished. Therefore, a condition of a high pressure and a high rotation in the above ranges is used to improve production efficiency. However, in this condition, the polishing pad 101 is easily elastically deformed at the CMP processing time.

When the CMP process is performed on the silicon oxide film 12 having an area equal to or larger than 2 mm×2 mm with a convexity coverage equal to or above 80%, for example, pressure is concentrated to edges of the convexities 13 of the silicon oxide film 12, and polishing of edges is selectively progressed. On the other hand, pressure decreases from the edges toward a center of the convexities 13. Pressure is practically not easily applied to portions near the center of the convexities 13 of the silicon oxide film 12, and the polishing is not easily progressed. Consequently, there is a tendency that flatness (global flatness) decreases.

In the first embodiment, a polishing pad of a high modulus of elasticity (high hardness) having 400 to 600 megapascals is used, and a polishing condition is set such that a polishing pressure is within 50 to 200 hectopascals and that a rotation number of the polishing pad is within 10 to 80 rpm. The modulus of elasticity is a measured value obtained by a nanoindenter method. A modulus of elasticity of an entire polishing pad (a bulk part) can be also measured by a dynamic viscoelasticity measuring method.

FIG. 4 is a schematic diagram for explaining the CMP process performed on a silicon oxide film by the polishing pad of a high modulus of elasticity according to the first embodiment. As shown in FIG. 4, in performing the CMP process on the silicon oxide film 12, a polishing slurry containing cerium oxide particles 31 and anionic surfactants 32 is supplied onto the polishing pad 22. Polycarboxylic acid or its salt can be also used for the anionic surfactants 32 in a similar manner to that of the conventional example. The cerium oxide particles 31 as abrasive grains are coated by the anionic surfactants 32, between the polishing pad 22 and the silicon oxide film 12.

In the first embodiment, when the polishing pad 22 having a high modulus of elasticity is used, elastic deformation of the polishing pad 22 can be suppressed at the CMP processing time. When a polishing pressure is set to a low value, elastic deformation of the polishing pad 22 can be more suppressed at the CMP processing time. In addition to this, when a rotation number of the polishing pad 22 is set to a low value, the cerium oxide particles 31 as abrasive grains are not easily scattered to the outside of the polishing pad 22, and the cerium oxide particles 31 can be easily fixed to the polishing pad 22. Consequently, flatness can be improved and efficient CMP process can be performed.

When a modulus of elasticity of the polishing pad 22 is lower than 400 megapascals, the polishing pad 22 is elastically deformed to a large extent at the CMP processing time, and a flatness improvement effect of the silicon oxide film 12 is small. When the modulus of elasticity of the polishing pad 22 is higher than 600 megapascals, scratch on the polished surface increases.

Further, when a polishing pressure is lower than 50 hectopascals, polishing speed decreases (convexity polishing force decreases), and a flatness improvement effect of the silicon oxide film 12 is small. When the polishing pressure is higher than 200 hectopascals, elastic deformation of the polishing pad 22 becomes large, and a flatness improvement effect of the silicon oxide film 12 is small. When a rotation number of the polishing pad 22 is smaller than 10 rpm, a supply shortage of the polishing slurry on the polished surface occurs due to a reduction of centrifugal force, and the polishing speed decreases. When the rotation number of the polishing pad is larger than 80 rpm, the cerium oxide particles 31 cannot be easily held on the polished surface due to centrifugal force, and there is a risk that flatness of the silicon oxide film 12 is degraded.

For the polishing pad 22 of a high modulus of elasticity, a polishing pad configured by a nonfoamed material, for example can be used. However, the material is not limited to this, and a polishing pad of a high modulus of elasticity configured by a foamed material can be also used.

In a conventional polishing slurry, the cerium oxide particles 31 as abrasive grains coated by the anionic surfactants 102 are not fixed to the polishing pad 101 as shown in FIG. 3. Therefore, free abrasive grains enter the concavities 14 of the silicon oxide film 12 and progress the polishing of the concavities 14. Due to the free abrasive grains, grains (the cerium oxide particles 103) valid to polish the convexities 13 of the silicon oxide film 12 decrease, and a selection ratio of polishing speed in the convexities 13 and polishing speed in the concavities 14 becomes low. Consequently, flatness of the silicon oxide film 12 tends to be insufficient.

Therefore, in another embodiment of the present invention, to increase a fixing effect of fixing the polishing particles (the cerium oxide particles 31) coated by the anionic surfactants 32 (polycarboxylic acid or its salt) to the polishing pad 22, there is used a polishing slurry containing the cerium oxide particles 31, the anionic surfactants 32, and resin particles 33 having a cationic surface functional group. FIG. 5 is a schematic diagram for explaining an effect obtained by containing the resin particles 33 having a cationic surface functional group in the polishing slurry.

The polishing pad (polishing cloth) 22 and the resin particles 33 are organic materials, and both can easily interact with each other based on intermolecular force (van der Waas force) between the organic materials. Further, the OH group and the COOH group are present on the surface of the polishing pad 22 generally made of a polyurethane resin, based on hydrolysis of the polyurethane resin, and these groups are charged in minus. Therefore, the resin particles 33 having a cationic surface functional group based on an electric interaction are adsorbed to the polishing pad 22. Further, the anionic surfactants 32 coated with the cerium oxide particles 31 as abrasive grains are charged in minus. Therefore, the resin particles 33 having a cationic surface functional group based on an electric interaction are also adsorbed to the cerium oxide particles 31.

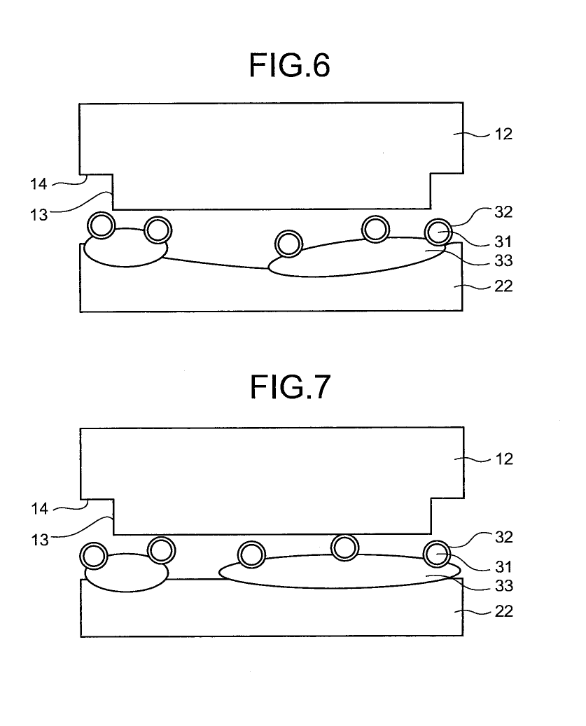

Accordingly, when the polishing slurry containing the cerium oxide particles 31 and the anionic surfactants 32 contains the resin particles 33 having a cationic surface functional group, the action of fixing the abrasive grains (the cerium oxide particles 31) to the polishing pad 22 occurs. This suppresses the entering of the abrasive grains (the cerium oxide particles 31) into the concavities 14 of the silicon oxide film 12. Consequently, only the convexities 13 of the silicon oxide film 12 can be efficiently polished. FIG. 6 is a schematic diagram for explaining a state that the cerium oxide particles 31 are fixed to the polishing pad 22 by arranging such that the polishing slurry contains the resin particles 33 having a cationic surface functional group. The resin particles 33 having a cationic surface functional group are adsorbed to the silicon oxide film 12, thereby protecting the concavities 14 of the silicon oxide film 12. Therefore, a selection ratio of the polishing speed in the convexities 13 and the polishing speed in the concavities 14 is improved, and flatness of the silicon oxide film 12 can be improved.

Preferably, concentration of the resin particles 33 having a cationic surface functional group in the polishing slurry is within a range of 0.001 wt % (weight percent) to 10 wt %. When the concentration of the resin particles 33 having a cationic surface functional group is lower than 0.001 wt %, flatness improvement effect of the silicon oxide film 12 is small. When the concentration of the resin particles 33 having a cationic surface functional group is higher than 10 wt %, the polishing speed becomes low, and flatness improvement effect of the silicon oxide film 12 is small.

Preferably, an average particle diameter of the resin particles 33 having a cationic surface functional group is within 10 nanometers to 3 micrometers. When the average particle diameter of the resin particles 33 having a cationic surface functional group is smaller than 10 nanometers, flatness improvement effect of the silicon oxide film 12 is small. When the average particle diameter of the resin particles 33 having a cationic surface functional group is larger than 3 micrometers, agglomeration of particles occurs, and scratch on the polished surface increases.

FIG. 7 is a schematic diagram for explaining a CMP process when a polishing pad of a high modulus of elasticity (high hardness) is combined with a polishing slurry containing resin particles having a cationic surface functional group. As shown in FIG. 7, when the CMP process is performed by combining the polishing pad 22 of a high modulus of elasticity (high hardness) configured by the nonfoamed material (nonfoamed polyurethane resin) with a polishing slurry containing the resin particles 33 having a cationic surface functional group, elastic deformation of the polishing pad 22 at the CMP processing time can be suppressed, and the cerium oxide particles 31 can be fixed to the polishing pad 22. Flatness of the silicon oxide film 12 can be further improved.

Further, in the first embodiment, agglomeration of the cerium oxide particles 31 and the anionic surfactants 32 is mitigated by decreasing a molecular weight of the anionic surfactants 32. With this arrangement, polishing speed sensitive to the polishing pressure can be obtained, and flatness of the silicon oxide film 12 can be improved. This is because particle agglomeration can be mitigated by weakening the interaction of a hydrophobic part of the surfactant adsorbed to the surface of the cerium oxide particles 31 as abrasive grains (polishing particles), based on a low molecular weight of the anionic surfactants 32.

A molecular weight of the anionic surfactants 32 is set within 500 to 10,000, and is preferably within 500 to 5,000. When the molecular weight of the anionic surfactants 32 is lower than 500, coating of the cerium oxide particles 31 by the anionic surfactants 32 becomes insufficient, and polishing progresses easily even when the polishing pressure is low. Therefore, flatness of the silicon oxide film 12 tends to be insufficient, and scratch on the polished surface increases. When the molecular weight of the anionic surfactants 32 is higher than 10,000, agglomeration of the cerium oxide particles 31 becomes large. Therefore, the polishing speed becomes low, and flatness of the silicon oxide film 12 tends to be insufficient.

Preferably, concentration of the anionic surfactants 32 in the polishing slurry is within a range of 0.001 wt % to 10 wt %. When the concentration of the anionic surfactants 32 is lower than 0.001 wt %, flatness of the silicon oxide film 12 tends to be insufficient. When the concentration of the anionic surfactants 32 is larger than 10 wt %, flatness of the silicon oxide film 12 tends to be insufficient, and scratch on the polished surface increases.

Meanwhile, preferably, concentration of the cerium oxide particles 31 as abrasive grains in the polishing slurry is within a range of 0.05 wt % to 10 wt %. When the concentration of the cerium oxide particles 31 is lower than 0.05 wt %, the polishing speed decreases. When the concentration of the cerium oxide particles 31 is higher than 10 wt %, scratch on the polished surface increases.

Preferably, a primary particle diameter of the cerium oxide particles 31 is within a range of 5 to 100 nanometers. When the primary particle diameter is smaller than 5 nanometers, the polishing speed decreases. When the primary particle diameter is larger than 100 nanometers, the particles tend to be agglomerated, and precipitation of particles agglomerated in the polishing slurry easily occurs. Therefore, scratch on the polished surface increases. The primary particle size of the cerium oxide particles 31 can be directly measured by a transmission electron microscope (TEM) or a scanning electron microscope (SEM), for example. In the first embodiment, the primary particle size is based on a value measured by the TEM.

Preferably, a secondary particle diameter of the cerium oxide particles 31 is within a range of 50 nanometers to 3 micrometers. When the secondary particle size is smaller than 50 nanometers, the polishing speed decreases. When the secondary particle size is larger than 3 micrometers, scratch on the polished surface increases. The secondary particle size is a measured value by a generally-used dynamic light scattering method for measuring a particle size based on a fluctuation of a scattered light by Brownian motion.

As described above, according to the semiconductor device manufacturing method in the first embodiment, in the planarizing process performed on the silicon oxide film 12 having a pattern formed in a region of 2 mm×2 mm or more with the convexity coverage equal to or larger than 80%, the polishing pad having a high modulus of elasticity (high hardness) within a range of 400 to 600 megapascals is used. The silicon oxide film 12 is polished at a polishing pressure within a range of 50 to 200 hectopascals, and in a rotation number within a range of 10 to 80 rpm. With this arrangement, elastic deformation of the polishing pad 22 at the CMP processing time can be suppressed, and the cerium oxide particles 31 as polishing particles can be easily fixed to the polishing pad 22. Consequently, flatness can be improved, and the CMP process can be performed efficiently.

According to a semiconductor device manufacturing method in another embodiment of the present invention, in the planarizing process performed on the silicon oxide film 12 having a pattern formed in a region of 2 mm×2 mm or more with the convexity coverage equal to or larger than 80%, there is used the polishing slurry containing the cerium oxide particles 31, the anionic surfactants 32, and the resin particles 33 having a cationic surface functional group. With this arrangement, entering of the abrasive grains (the cerium oxide particles 31) into the concavities 14 of the silicon oxide film 12 can be suppressed, and the abrasive grains (the cerium oxide particles 31) can be fixed to the polishing pad 22. Accordingly, only the convexities 13 of the silicon oxide film 12 can be efficiently polished. Further, the resin particles 33 having a cationic surface functional group are adsorbed to the silicon oxide film 12, and protect the concavities 14 of the silicon oxide film 12. Consequently, a selection ratio of the polishing speed in the convexities 13 and the polishing speed in the concavities 14 is improved, and flatness of the silicon oxide film 12 can be improved.

According to the semiconductor device manufacturing method of the first embodiment, in the planarizing process performed on the silicon oxide film 12 having a pattern formed in a region of 2 mm×2 mm or more with the convexity coverage equal to or larger than 80%, a molecular weight of the anionic surfactants 32 is decreased in a state of satisfying at least one of the use of the polishing slurry containing the cerium oxide particles 31, the anionic surfactants 32, and the resin particles 33 having a cationic surface functional group, and the use of the polishing pad 22 having a high modulus of elasticity (high hardness) with a low setting of the polishing pressure and a low setting of the rotation number of the polishing pad 22. With this arrangement, agglomeration of the cerium oxide particles 31 and the anionic surfactants 32 is mitigated. Consequently, polishing speed sensitive to the polishing pressure can be obtained, and flatness of the silicon oxide film 12 can be improved.

Therefore, according to the semiconductor device manufacturing method in the first embodiment, a planarizing process of high flatness can be performed on the pattern of the silicon oxide film 12.

The semiconductor device manufacturing method according to the first embodiment can be suitably used to manufacture devices such as a complementary metal oxide semiconductor (CMOS) image sensor. A device such as a CMOS image sensor includes peripheral circuits, and pixels occupying a large area within a semiconductor chip. The pixels have a dense and finer pattern than that of the peripheral circuits. Therefore, in the pixels, a recess between fine and dense patterns of gates and the like is blocked at the time of forming a PMD covering a substrate on which transistors and the like are formed beneath a metal wiring layer as a first layer. As a result, a region of a large area of convexities is sometimes formed in the pixels.

When a large area of convexities is planarized by the CMP, dishing occurs and flatness tends to be degraded. The pattern of the pixels has a strict design constraint, and the degradation of flatness cannot be avoided by designing. On the other hand, for the large area of convexities, there is considered a method of planarizing the convexities by the CMP, after forming a fine irregular pattern by applying a lithography method and a dry etching method such as a reactive ion etching (RIE) to the blocked PMD film. However, in this case, much work is necessary to design an irregular pattern suitable for the CMP, and a number of processes and process cost increase substantially. Therefore, when the above-described semiconductor device manufacturing method according to the first embodiment is used, a planarizing process of high flatness can be performed to the region of a large area of convexities formed in the pixels, without increasing the number of processes.

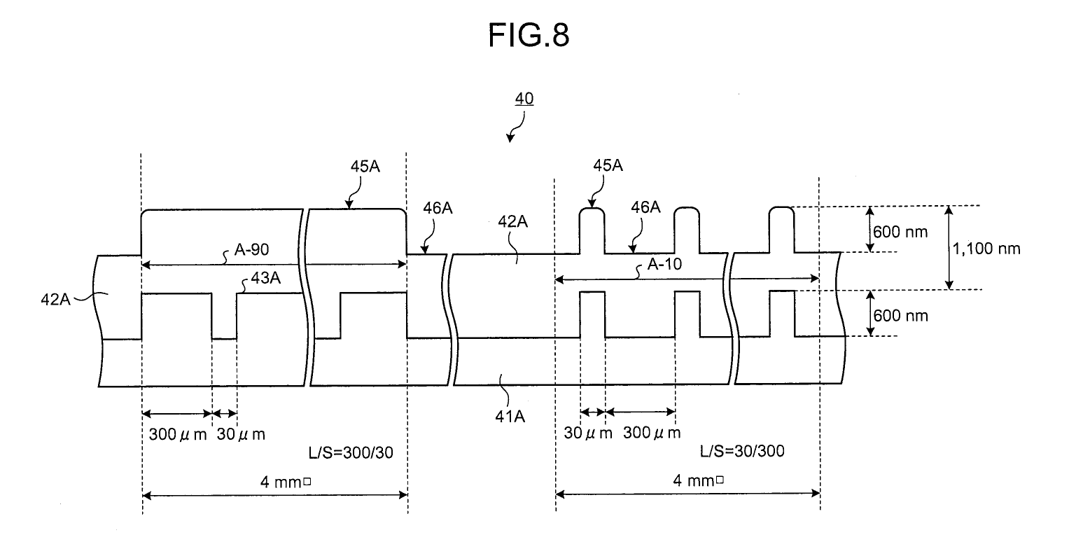

Examples to which the semiconductor device manufacturing method according to the first embodiment is applied are explained below in comparison with comparative examples. FIG. 8 is a schematic diagram for explaining a sample of a pattern A. First, as shown in FIG. 8, steps 43A having a height of 600 nanometers were formed on a silicon substrate 41A by a normal lithography method and a normal dry etching method. A size of line and space of the steps 43A was changed to form a pattern A having a region A-90 of a high convexity coverage (90%) and a region A-10 having a low convexity coverage (10%). The region A-90 and the region A-10 have an area of 4 mm×4 mm, respectively. A silicon oxide film (SiO₂ film) 42A was formed in a thickness of 1,100 nanometers on the silicon substrate 41A by a chemical vapor deposition (CVD) method, thereby manufacturing a sample 40 of the pattern A. Convexities 45A and concavities 46A were formed on the silicon oxide film 42A.

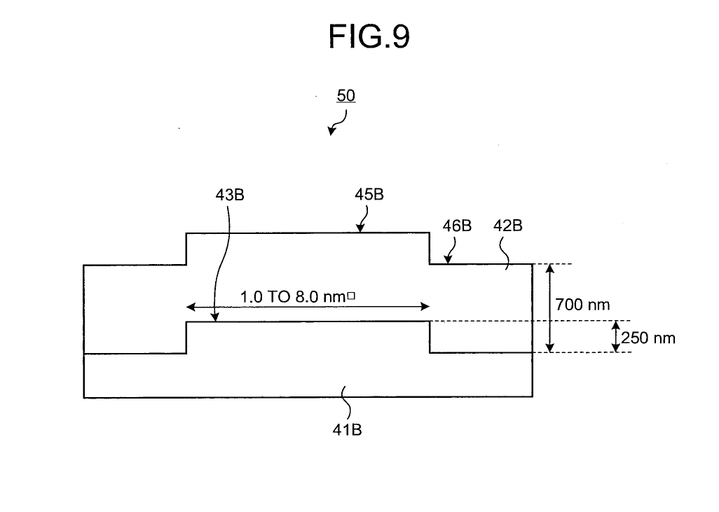

FIG. 9 is a schematic diagram for explaining a sample of a pattern B. As shown in FIG. 9, a step 43B of 250 nanometers was formed on a silicon substrate 41B by the normal lithography method and the normal dry etching method. The pattern B of 1 mm×1 mm, 2 mm×2 mm, 3 mm×3 mm, 4 mm×4 mm, 5 mm×5 mm, 6 mm×6 mm, 7 mm×7 mm, and 8 mm×8 mm was formed on the step 43B. A silicon oxide film (SiO₂ film) 42B was formed in a thickness of 700 nanometers on the silicon substrate 41B by the CVD method, thereby forming a sample 50 of the pattern B. Convexities 45B and concavities 46B were formed on the silicon oxide film 42B.

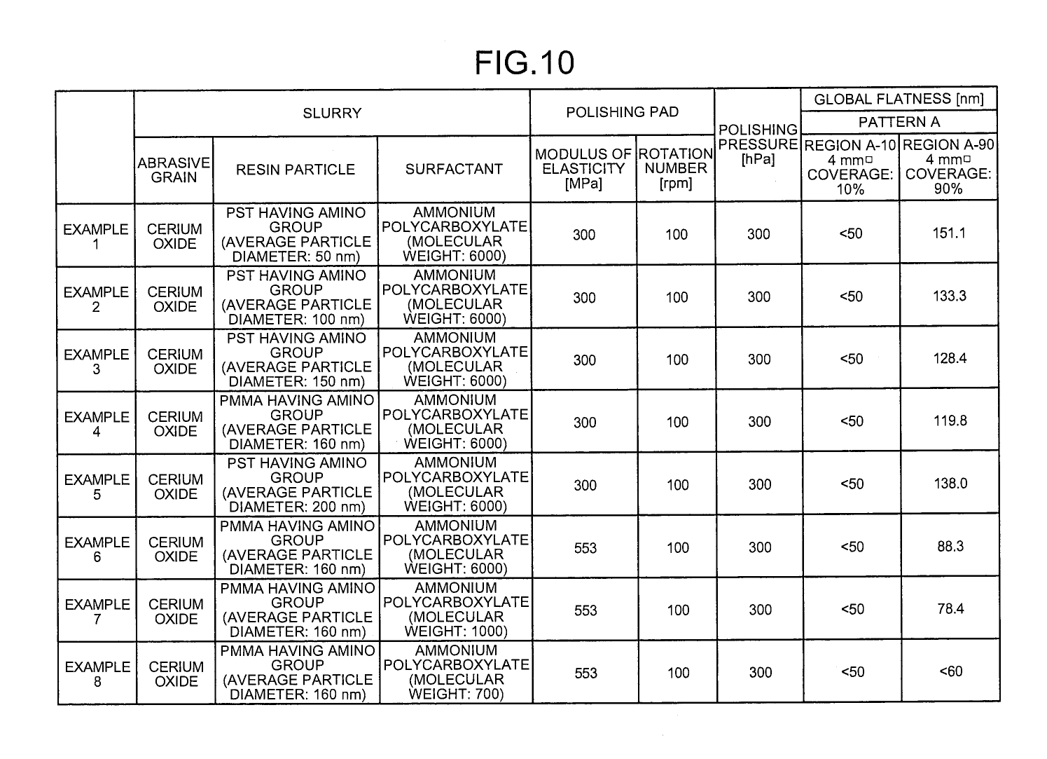

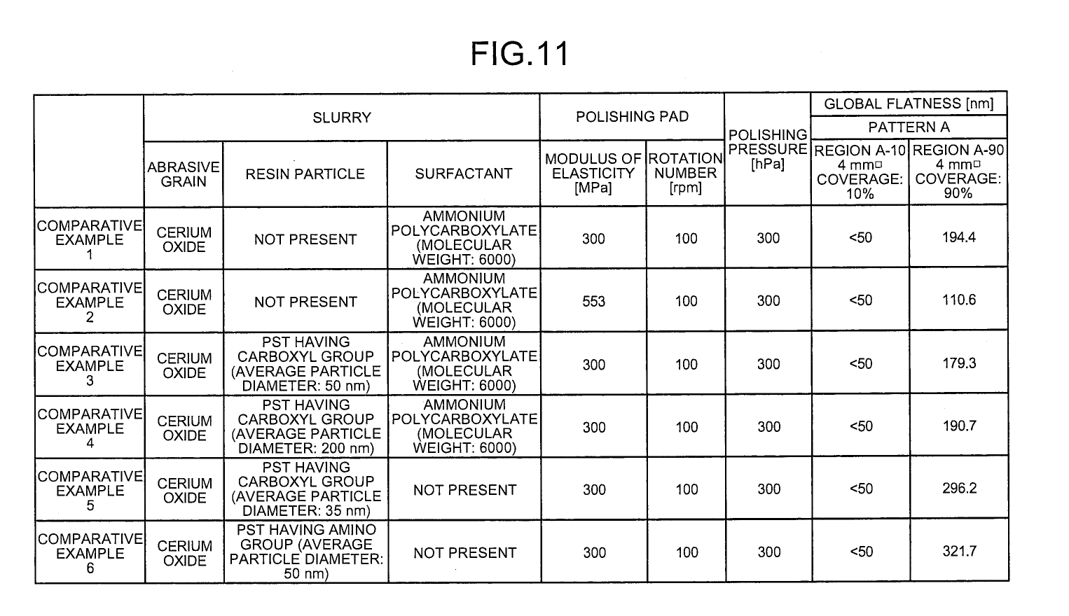

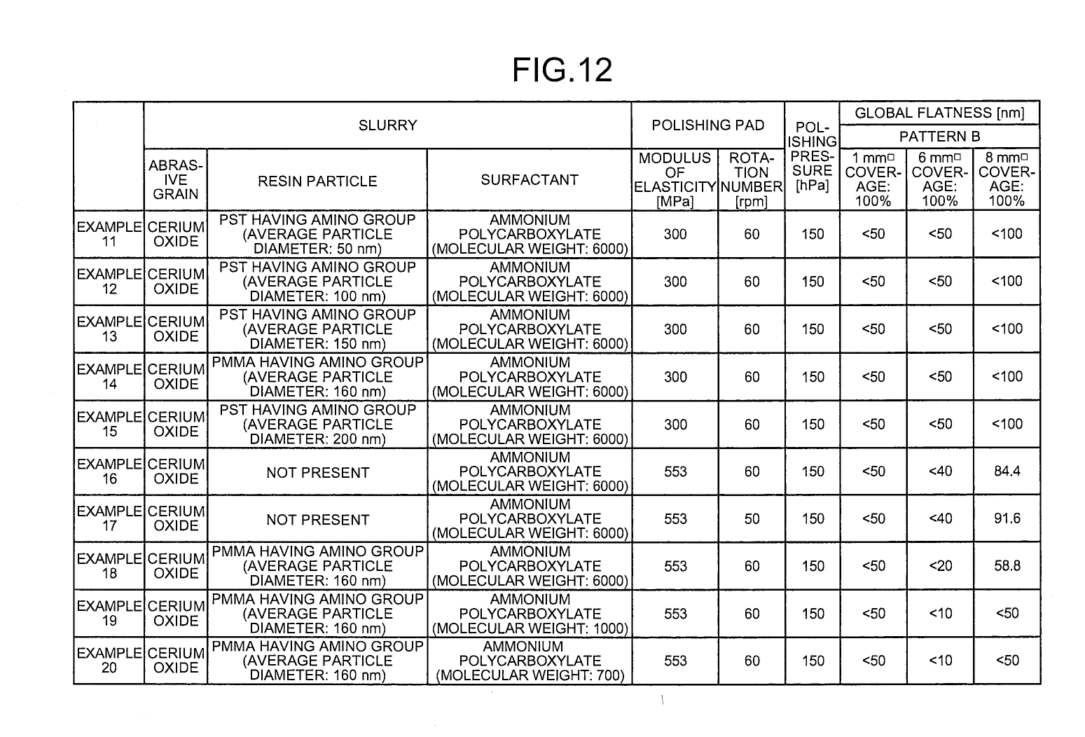

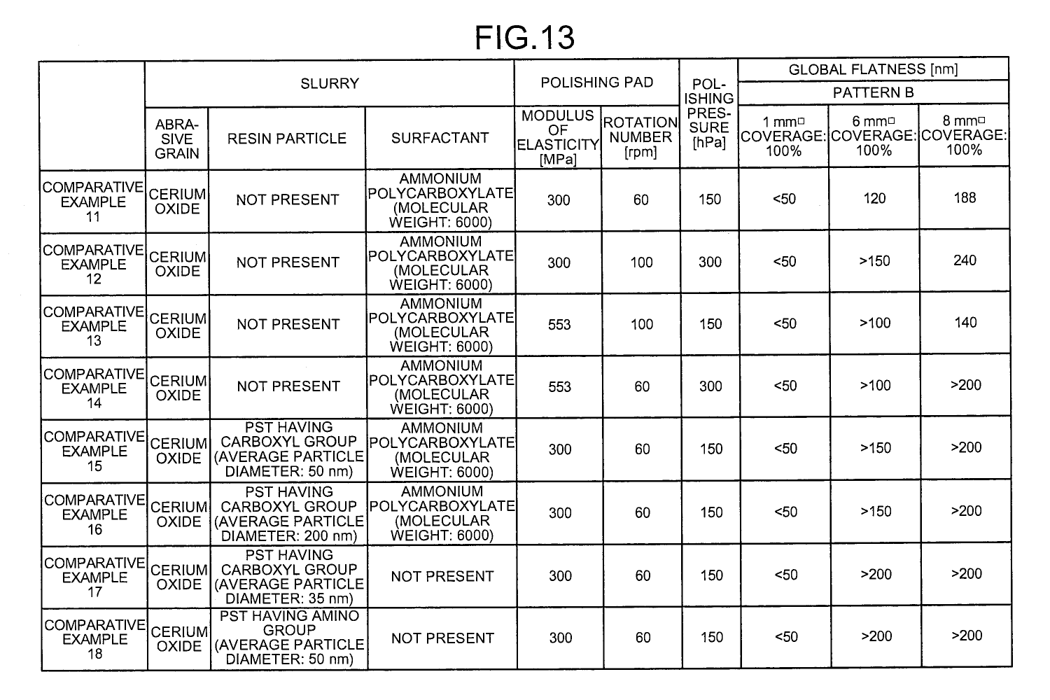

By the CMP method using the polishing device shown in FIG. 2, the samples of the patterns A and B were polished until when a polishing amount of the concavities became equal to or larger than 200 nanometers, and the patterns of the silicon oxide films (the SiO₂ films) were planarized. FIG. 10 depicts detailed CMP processing conditions of each example (Example 1 to Example 8) of the pattern A, FIG. 11 depicts detailed CMP processing conditions of each comparative example (Comparative example 1 to Comparative example 6) of the pattern A, FIG. 12 depicts detailed CMP processing conditions of each example (Example 11 to Example 20) of the pattern B, and FIG. 13 depicts detailed CMP processing conditions of each comparative example (Comparative example 11 to Comparative example 18) of the pattern B. A polishing slurry and a polishing pad used for the CMP method were as follows.

### <Polishing Slurry>

The polishing slurry used contained cerium oxide particles and anionic surfactants in pure water, and resin particles having a cationic surface functional group when required. An adjustment condition of the polishing slurry was as follows.

### [Cerium Oxide]

Cerium oxide used for the abrasive grains was DLS2 (primary particle diameter 100 nanometers) manufactured by Hitachi Chemical Co., Ltd., in all examples and all comparative examples. This cerium oxide was contained in concentration of 0.5 wt % into the polishing slurry.

### [Anionic Surfactants]

In Example 1 to Example 6, Example 11 to Example 18, Comparative example 1 to Comparative example 4, and Comparative example 11 to Comparative example 16, as ammonium polycarboxylate, TK75 (molecular weight 6,000) manufactured by Kao Corporation was used. This ammonium polycarboxylate was contained in concentration of 0.7 wt % into the polishing slurry. In Example 7 and Example 19, ammonium polycarboxylate: KDH93 (molecular weight 1,000) manufactured by Kao Corporation was used. This ammonium polycarboxylate was contained in concentration of 0.7 wt % into the polishing slurry. In Example 8 and Example 20, ammonium polycarboxylate: KDH93 (molecular weight 700) manufactured by Kao Corporation was used. This ammonium polycarboxylate was contained in concentration of 0.7 wt % into the polishing slurry. No anionic surfactant was contained into the polishing slurry, in Comparative example 5, Comparative example 6, Comparative example 17, and Comparative example 18.

### [Resin Particles Having Cationic Surface Functional Group]

In Example 1 to Example 3, Example 5, Example 11 to Example 13, Example 15, and Comparative example 6 and Comparative example 18, polystyrenes (PST) having the amino group manufactured by JSR Corporation having average particle diameters shown in FIG. 10 to FIG. 13 were used. Each polystyrene was contained in concentration of 0.1 wt % into the polishing slurry. In Example 4, Example 6 to Example 8, Example 14, and Example 18 to Example 20, polymethylmethacrylates (PMMA) having amino group manufactured by JSR Corporation having average particle diameters shown in FIG. 10 and FIG. 12 were used. Each polymethylmethacrylate was contained in concentration of 0.1 wt % into the polishing slurry. In Example 16, Example 17, Comparative example 1, Comparative example 2, and Comparative example 11 to Comparative example 14, resin particles having a cationic surface functional group were not contained. In Comparative example 3 to Comparative example 5, and Comparative example 15 to Comparative example 17, polystyrenes (PST) having the carboxyl group manufactured by JSR Corporation having average particle diameters shown in FIG. 11 and FIG. 13 were used, instead of resin particles having a cationic surface functional group. Each polystyrene was contained in concentration of 0.1 wt % into the polishing slurry.

### <Polishing Pad>

In Example 1 to Example 5, Example 11 to Example 15, Comparative example 1, Comparative example 3 to Comparative example 6, Comparative example 11, Comparative example 12, and Comparative example 15 to Comparative example 18, IC1000/Suba 400 (modulus of elasticity 300 megapascals) manufactured by Rohm and Haas Company was used. In Example 6 to Example 8, Example 16 to Example 20, Comparative example 2, Comparative example 13, and Comparative example 14, NCP-1 (modulus of elasticity 553 megapascals) manufactured by Nihon Micro Coating Co., Ltd. was used.

The samples of the patterns A and B were CMP processed in each condition of Example 1 to Example 8 and Example 11 to Example 20 as the examples of the present invention, and Comparative example 1 to Comparative example 6 and Comparative example 11 to Comparative example 18 to be compared. Classifications of the examples were as follows. In each example (Example 1 to Example 8) of the pattern A and in each comparative example (Comparative example 1 to Comparative example 6), a rotation number of the polishing pad and a polishing pressure are all in the same conditions.

### Example 1 to Example 5

A polishing slurry containing resin particles having the amino group as the cationic surface function group, with a resin particle size changed, was used.

### Example 6

A polishing pad of a high modulus of elasticity (high hardness) was used. A polishing slurry containing resin particles having the amino group as a cationic surface functional group was used.

### Example 7 and Example 8

A polishing pad of a high modulus of elasticity (high hardness) was used. A polishing slurry containing low-molecular-weight surfactants and resin particles having the amino group as a cationic surface functional group was used. A molecular weight of the low-molecular-weight surfactants was changed.

### Example 11 to Example 15

A polishing slurry containing resin particles having the amino group as the cationic surface function group, with a resin particle size changed, was used.

### Example 16 and Example 17

A polishing pad of a high modulus of elasticity (high hardness) was used. A polishing pressure and a rotation number of the polishing pad were set to low values.

### Example 18

A polishing pad of a high modulus of elasticity (high hardness) was used. A polishing pressure and a rotation number of the polishing pad were set to low values. A polishing slurry containing resin particles having the amino group as a cationic surface functional group was used.

### Example 19 and Example 20

A polishing pad of a high modulus of elasticity (high hardness) was used. A polishing pressure and a rotation number of the polishing pad were set to low values. A polishing slurry containing low-molecular-weight surfactants and resin particles having the amino group as a cationic surface functional group was used. A molecular weight of the low-molecular-weight surfactants was changed.

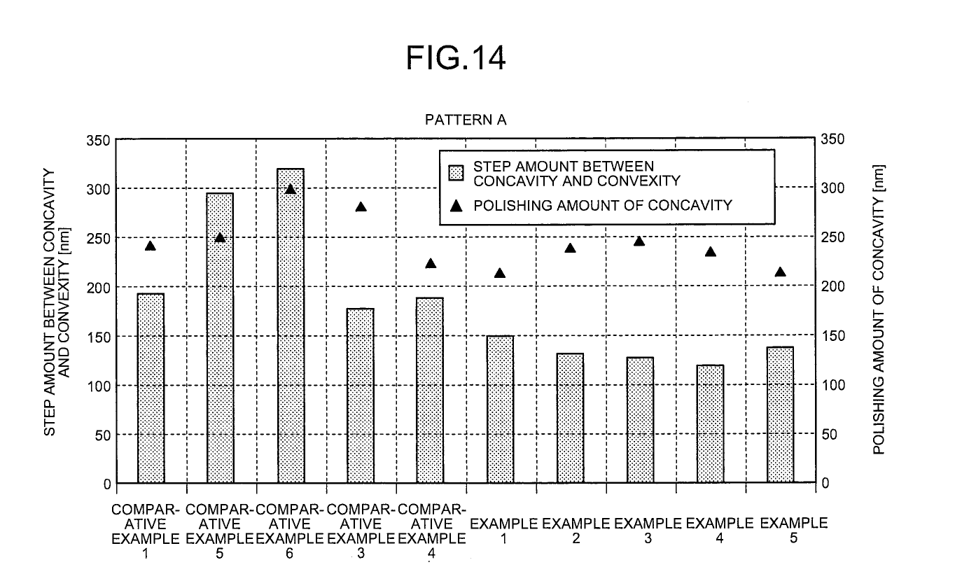

FIG. 10 and FIG. 11 depict step amounts (global flatness) between the convexities 45A and the concavities 46A, as CMP processing results of the examples and the comparative examples of the sample of the pattern A. FIG. 14 depicts step amounts (global flatness) between the convexities 45A and the concavities 46A in the region A-90 of the sample of the pattern A, and polishing amounts of the concavities 46A.

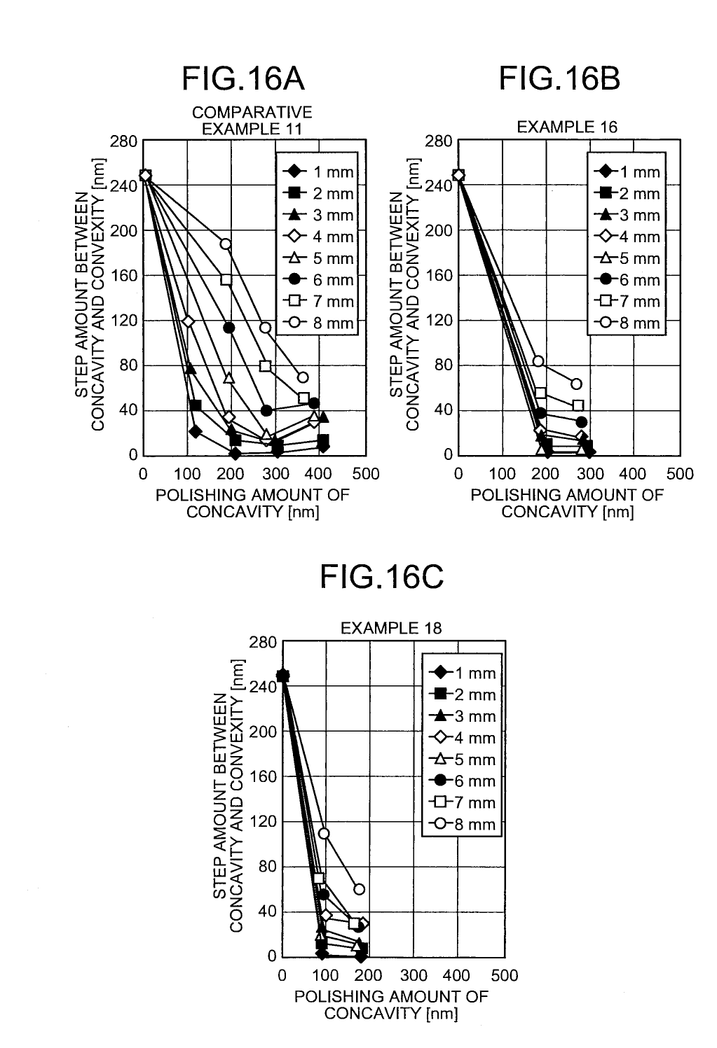

FIGS. 12 and 13 and FIG. 15A to FIG. 16C depict step amounts (global flatness) between the convexities 45B and the concavities 46B, as CMP processing results of the examples and the comparative examples of the sample of the pattern B. FIG. 16A to FIG. 16C collectively depict a relationship between the polishing amount of the concavities 46B, and the step amounts (global flatness) between the convexities 45B and the concavities 46B, for the samples of the convexity areas 1 to 8 mm×8 mm in Example 16, Example 18, and Comparative example 11.

First, for the sample of the pattern A, in both of the examples and the comparative examples, the global flatness has a small step value (smaller than 50 nanometers) in the region A-10 having the low convexity coverage (10%) in the sample of the pattern A, as is understood from FIG. 10 and FIG. 11. As a result, satisfactory flatness is obtained.

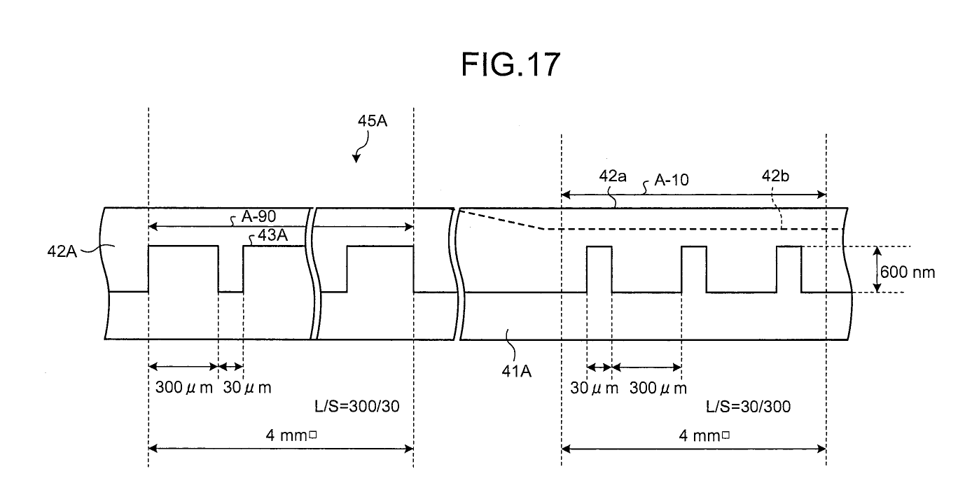

Meanwhile, in the region A-90 having the high convexity coverage (90%) in the sample of the pattern A, the step amount in Example 1 to Example 5 substantially decreases from that of Comparative example 1. An improvement effect of the global flatness is recognized as a result of containing the resin particles having a cationic surface functional group into the polishing slurry containing cerium oxide and anionic surfactants. FIG. 17 is a schematic diagram of a state of the polished surface after the CMP process in Example 1 and Comparative example 1. In Comparative example 1, a polished surface 42b after the CMP process is low in the region A-10, and the global flatness is not satisfactory in the region A-90 of the high convexity coverage (90%) and the region A-10 of the low convexity coverage (10%). On the other hand, in Example 1, a polished surface 42a after the CMP process is approximately a plane surface, and has satisfactory flatness.

As Comparative example 2 is compared with Example 6 in which the modulus of elasticity of the polishing pad is changed from those of Example 1 to Example 5 and Comparative 1, a step amount in Example 6 decreases more than that of Comparative example 2. Even when the condition of the modulus of elasticity of the polishing pad changes, an improvement effect of the global flatness is recognized as a result of containing the resin particles having a cationic surface functional group into the polishing slurry containing cerium oxide and anionic surfactants.

In Example 7 and Example 8 in which the molecular weight of the anionic surfactants is changed from that of Example 6, a step amount decreases more than that in Example 6. Even when the molecular weight of the anionic surfactants is changed, an improvement effect of the global flatness is recognized as a result of containing the resin particles having a cationic surface functional group into the polishing slurry containing cerium oxide and anionic surfactants.

As Example 1 to Example 5 are compared with Comparative example 3 and Comparative example 4, a step amount decreases in Example 1 to Example 5 more than that in Comparative example 3 and Comparative example 4. An improvement effect of the global flatness is not obtained even when the resin particles having the anionic surface functional group are contained into the polishing slurry containing cerium oxide and anionic surfactants. An improvement effect of the global flatness is recognized based on the containing of the resin particles having a cationic surface functional group into the polishing slurry containing cerium oxide and anionic surfactants. As Comparative example 3 and Comparative example 4 are compared with Comparative example 5, when the resin particles having the anionic surface functional group are contained into the polishing slurry, a step amount becomes a larger value when the anionic surfactants are not contained.

As Example 1 is compared with Comparative example 6, a step difference decreases more than that of Comparative example 6. To improve the global flatness by containing the resin particles having a cationic surface functional group into the polishing slurry containing cerium oxide, it is necessary to contain the anionic surfactants together.

Therefore, from the above result, it is safe to say that in the sample of the pattern A, an improvement effect of the global flatness is recognized by the polishing slurry containing the cerium oxide particles, the anionic surfactants, and the resin particles having a cationic surface functional group.

Regarding the sample of the pattern B, as is understood from FIG. 12 and FIG. 13, in the pattern having the convexity area of 1 mm×1 mm, the global flatness has the small step value (smaller than 50 nanometers) in both the examples and the comparative examples, and satisfactory flatness is obtained.

In the pattern having a convexity area of 6 mm×6 mm, as is understood from FIG. 12 and FIG. 13, at least the global flatness has a larger step than 100 nanometers in the comparative examples, and the small step value (smaller than 50 nanometers) is obtained in the examples, thereby having satisfactory flatness.

In Example 11 to Example 15, a step amount decreases more than that in Comparative example 11. An improvement effect of the global flatness is recognized by the polishing slurry containing the resin particles having a cationic surface functional group into the polishing slurry containing cerium oxide and anionic surfactants. It is understood from Comparative example 15 and Comparative example 16 that when the resin particles having the anionic surface functional group are contained into the polishing slurry containing cerium oxide and anionic surfactants, an improvement effect of the global flatness as obtained in Example 11 to Example 15 is not obtained. In Comparative example 17 and Comparative example 18, a step amount becomes a very large equivalent value. To improve the global flatness by containing the resin particles having a cationic surface functional group into the polishing slurry containing cerium oxide, it is necessary to contain anionic surfactants together.

In Example 16 and Example 17, the global flatness decreases more than that in Comparative example 11 and Comparative example 12. An improvement effect of the global flatness is recognized by using of the polishing pad having a high modulus of elasticity (high hardness) and by setting of the polishing pressure and the rotation number of the polishing pad to low values. It is understood from Comparative example 13 and Comparative example 14 that even when the polishing pad having a high modulus of elasticity (high hardness) is used, the improvement effect of the global flatness is insufficient unless the polishing pressure and the rotation number of the polishing pad are set to low values.

In Example 18, the global flatness decreases more than that in Example 16 and Example 17. A further improvement effect of the global flatness is recognized based on a combination of the use of the polishing slurry containing cerium oxide particles, anionic surfactants, and resin particles having a cationic surface functional group, the use of the polishing pad having a high modulus of elasticity (high hardness), and the setting of the polishing pressure and the rotation number of the polishing pad to low values.

In Example 19 and Example 20, a step amount decreases by more than 110 nanometers as compared with a decrease in Comparative example 11. A further improvement effect of the global flatness is recognized based on the use of the polishing slurry containing cerium oxide, anionic surfactants, and resin particles having a cationic surface functional group, the use of the polishing pad having a high modulus of elasticity (high hardness), the setting of the polishing pressure and the rotation number of the polishing pad to low values, and the setting of a molecular weight of the anionic surfactants to a low value.

As is understood from FIG. 12 and FIG. 13, the global flatness of the pattern having a convexity area of 8 mm×8 mm also has a similar tendency to that of the pattern having the convexity area of 6 mm×6 mm. An improvement effect of the global flatness is recognized based on the use of the polishing slurry containing cerium oxide particles, anionic surfactants, and resin particles having a cationic surface functional group, the use of the polishing pad having a high modulus of elasticity (high hardness), the setting of the polishing pressure and the rotation number of the polishing pad to low values, and the setting of a molecular weight of the anionic surfactants to a low value.

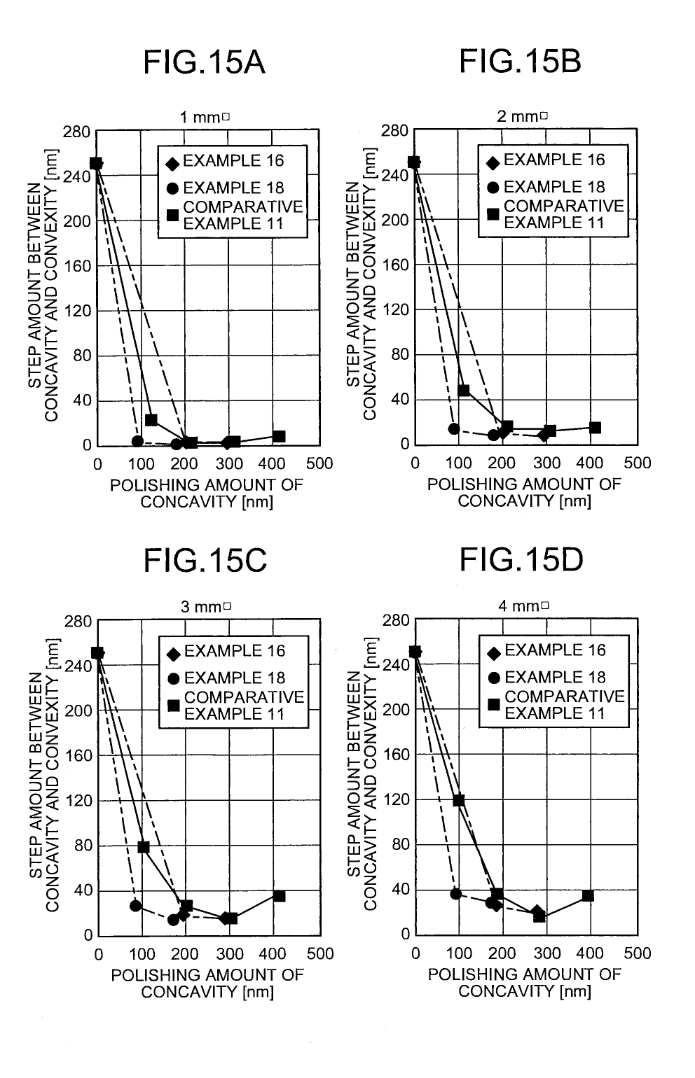

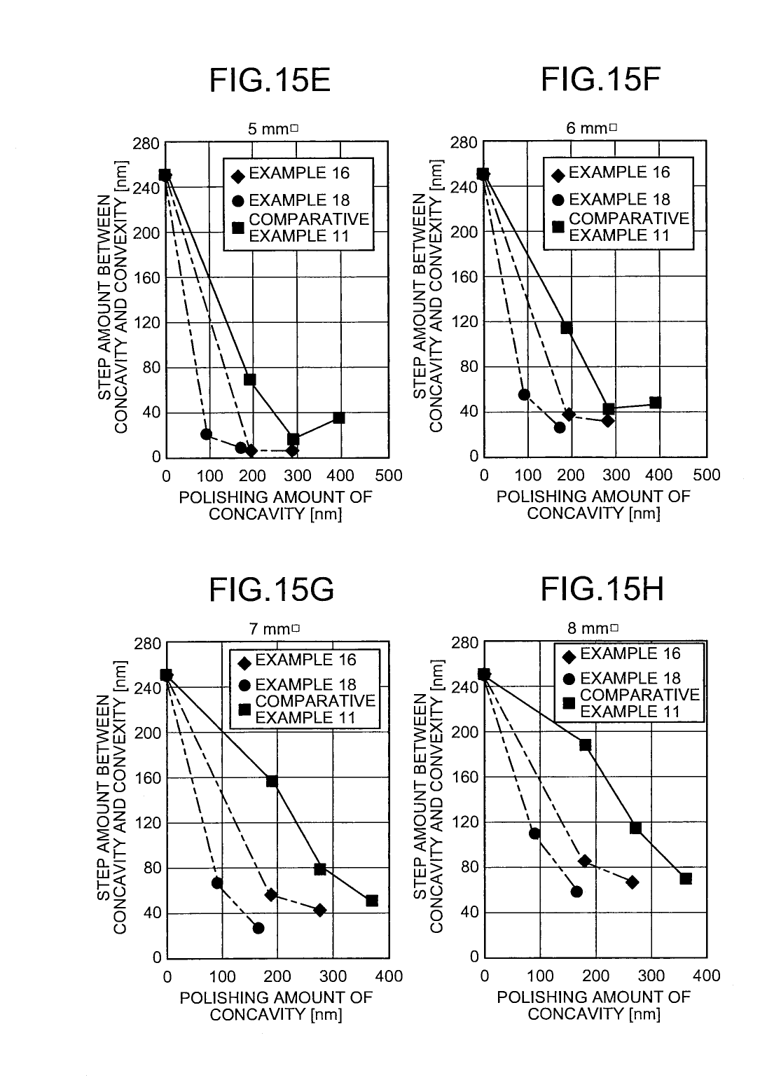

As Example 16, Example 18, and Comparative example 11 are compared with each other, as is understood from FIG. 15A to FIG. 16C, a dependency of a planarization characteristic on the convexity area is large in Comparative example 11 which uses the conventional polishing slurry and the conventional polishing pad. That is, when the convexity area becomes large, a polishing amount of the concavities required for the planarization becomes large. When the polishing amount of the concavities is not increased (when the concavities are not polished deep), a step amount between the convexities and the concavities does not become small, and the planarization characteristic is not satisfactory.

On the other hand, in Example 16 and Example 18, as is understood from FIG. 15A to FIG. 16C, the dependency of a planarization characteristic on the convexity area is small. That is, even when the convexity area becomes large, an increment of a polishing amount of the concavities required for the planarization is small. This is based on the fact that in Example 16 and Example 18, elastic deformation of the polishing pad is suppressed, and the abrasive grain is fixed to the polishing pad, and consequently, only the convexities 45B can be selectively efficiently planarized. That is, high global flatness can be achieved by a smaller polishing amount of the concavities.

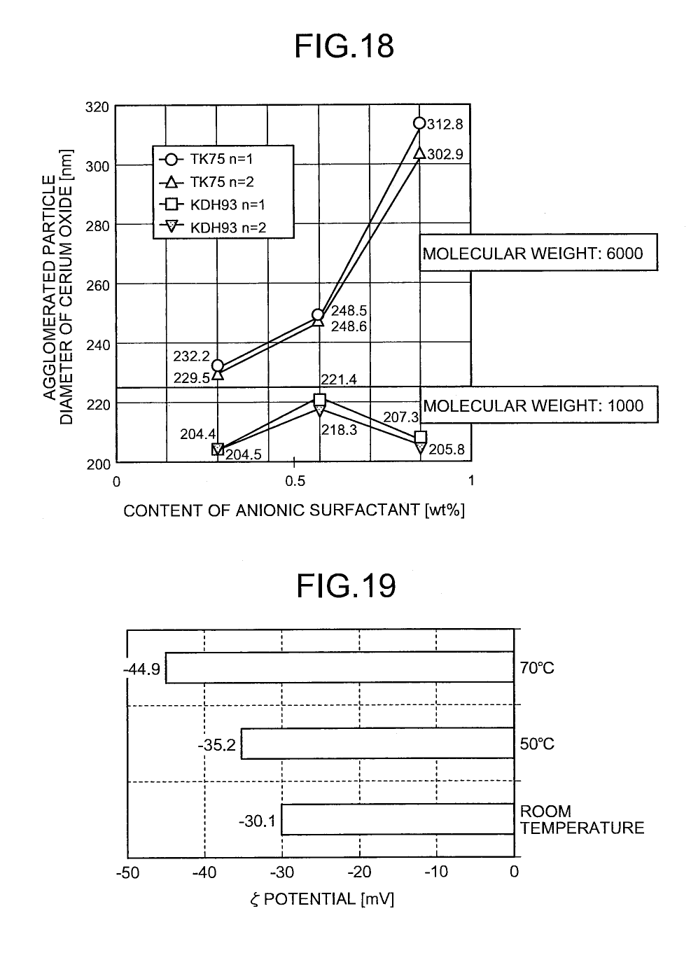

FIG. 18 depicts a relationship between a content of anionic surfactants in the polishing slurry and an agglomerated particle diameter (secondary particle diameter) of cerium oxide, in Example 18 in which the molecular weight of the anionic surfactants is 6,000 and Example 19 in which the molecular weight of the anionic surfactants is 1,000. In FIG. 18, n represents a number of times of measuring agglomerated particle diameters, and the agglomerated particle diameters are measured at two times (n=1, n=2) before performing the CMP process. The agglomerated particle diameters are measured by the dynamic light scattering method.

When the molecular weight of the anionic surfactants is 6,000 and when the anionic surfactants are contained in 0.85 wt %, the agglomerated particle diameter of cerium oxide exceeds 300 nanometers. Meanwhile, when the molecular weight of the anionic surfactants is 1,000 and when the anionic surfactants are contained in 0.85 wt %, the agglomerated particle diameter of cerium oxide is about 200 nanometers.

Generally, when the content of the anionic surfactants increases, the agglomerated particle diameter of cerium oxide particles tends to increase. It can be understood that when the molecular weight of the anionic surfactants is decreased, increase of the agglomerated particle diameter of cerium oxide particles can be suppressed. Accordingly, polishing speed sensitive to the polishing pressure can be obtained, and flatness of the silicon oxide film can be improved.

When the global flatness of the pattern having the convexity area of 6 mm×6 mm is compared with the global flatness of the pattern having the convexity area of 8 mm×8 mm for Example 18 in which the molecular weight of the anionic surfactants is 6,000 and Example 19 in which the molecular weight of the anionic surfactants is 1,000, it can be understood that the global flatness in Example 19 is more improved than that in Example 18. Accordingly, it is safe to say that an improvement effect of the global flatness is recognized based on the use of the polishing slurry containing cerium oxide particles, anionic surfactants, and resin particles having a cationic surface functional group, the use of the polishing pad having a high modulus of elasticity (high hardness), the setting of the polishing pressure and the rotation number of the polishing pad to low values, and the setting of a molecular weight of the anionic surfactants to a low value.

Therefore, from the above result, for the sample of the pattern B, it is safe to say that an improvement effect of the global flatness is recognized based on the use of the polishing slurry containing cerium oxide particles, anionic surfactants, and resin particles having a cationic surface functional group, the use of the polishing pad having a high modulus of elasticity (high hardness), the setting of the polishing pressure and the rotation number of the polishing pad to low values, combinations of the use and setting, and the setting of a molecular weight of the anionic surfactants to a low value.

### Second Embodiment

In a second embodiment of the present invention, examples of improving the planarization characteristic by suppressing a reduction of the polishing characteristic attributable to the increase of a temperature of a polishing slurry are explained when the polishing slurry used contains the above cerium oxide particles, the anionic surfactants, and the resin particles having a cationic surface functional group.

In the planarizing process of the CMP method using a polishing slurry containing cerium oxide particles, anionic surfactants, and resin particles having a cationic surface functional group, when a number of the cerium oxide particles as abrasive grains contained in the polishing slurry is large, polishing action between the silicon oxide film, the abrasive grains (the cerium oxide particles), and the polishing pad becomes large, thereby generating many frictions between the silicon oxide film, the abrasive grains (the cerium oxide particles), and the polishing pad. Therefore, a temperature of the polishing slurry rises at an early stage after starting the polishing. When a temperature of the polishing slurry rises, a ζ (zeta) potential of the polishing slurry increases in negative. When the ζ potential of the polishing slurry increases in negative, the cerium oxide particles and the anionic surfactants are easily adsorbed to each other. Accordingly, many anionic surfactants are more firmly adsorbed to the cerium oxide particles, and are agglomerated.

For example, when the resin particles 33 having a cationic surface functional group are contained in the polishing slurry as shown in FIG. 6, the cerium oxide particles 31 are fixed to the polishing pad 22. Further, the resin particles 33 having a cationic surface functional group are adsorbed to the silicon oxide film 12, thereby protecting the concavities 14 of the silicon oxide film 12. Therefore, a selection ratio of the polishing speed of the convexities 13 and the polishing speed of the concavities 14 is improved, thereby improving the flatness of the silicon oxide film 12. However, when the temperature of the polishing slurry rises, too many anionic surfactants are adsorbed to the abrasive grains (the cerium oxide particles). Accordingly, the polishing speed of the convexities 13 as high polishing speed is significantly lowered based on a surface protection effect of the anionic surfactants on the abrasive grains (the cerium oxide particles). Consequently, the selection ratio of the polishing speed of the convexities 13 and the polishing speed of the concavities 14 decreases. The decrease of the selection ratio of the polishing speed aggravates the planarization characteristic.

FIG. 19 depicts characteristics of a change of the ζ potential when a temperature of the polishing slurry containing cerium oxide particles as abrasive grains and ammonium polycarboxylate as the anionic surfactants is changed. There are three kinds of temperatures, i.e., a room temperature, 50° C., and 70° C., for the polishing slurry. The ζ potential is a value measured by an electrophoresis method.

As shown in FIG. 19, the ζ potential of the polishing slurry is −30.1 millivolts when the temperature of the polishing slurry is the room temperature. The ζ potential is −35.2 millivolts when the temperature of the polishing slurry is 50° C. The ζ potential is −44.9 millivolts when the temperature of the polishing slurry is 70° C. In this way, the ζ potential of the polishing slurry increases in negative when the temperature of the polishing slurry rises. Accordingly, in the polishing slurry at 50° C., more anionic surfactants are more firmly adsorbed to the abrasive grains (the cerium oxide particles) and agglomerated than the anionic surfactants in the polishing slurry at the room temperature. In the polishing slurry at 70° C., more anionic surfactants are more firmly adsorbed to the abrasive grains (the cerium oxide particles) and agglomerated than the anionic surfactants in the polishing slurry at 50° C.

That is, the polishing slurry at 50° C. has a larger surface-protection effect of the anionic surfactants on the abrasive grains (the cerium oxide particles) than that of the polishing slurry at the room temperature. Therefore, at the CMP processing time of the silicon oxide film, the polishing slurry at 50° C. significantly lowers the convexity polishing speed as the high polishing speed. Further, the polishing slurry at 70° C. has a larger surface-protection effect of the anionic surfactants on the abrasive grains (the cerium oxide particles) than that of the polishing slurry at 50° C. Therefore, at the CMP processing time of the silicon oxide film, the polishing slurry at 70° C. more significantly lowers the convexity polishing speed as the high polishing speed.

Accordingly, in the CMP process of the silicon oxide film using the polishing slurry at 50° C., the selection ratio of the polishing speed in the convexities 13 and the polishing speed in the concavities 14 becomes lower than the selection ratio when the polishing slurry at the room temperature is used. Consequently, the planarization characteristic is aggravated. In the CMP process of the silicon oxide film using the polishing slurry at 70° C., the selection ratio of the polishing speed in the convexities 13 and the polishing speed in the concavities 14 becomes lower than the selection ratio when the polishing slurry at 50° C. is used. As a result, the planarization characteristic is more aggravated.

While the above polishing slurries do not contain resin particles having a cationic surface functional group, when the polishing slurries contain resin particles having a cationic surface functional group, the influence that the change of the ζ potential due to the rise in the temperature of the polishing slurries gives to the polishing remains the same as that described above.

In the second embodiment, the temperature of the polishing slurry at the CMP processing time is lowered. With this arrangement, a state of adsorption of the anionic surfactants to the abrasive grains (the cerium oxide particles) is mitigated, thereby suppressing a reduction of the selection ratio of the polishing speed in the convexities 13 and the polishing speed in the concavities 14, and improving the planarization characteristic.

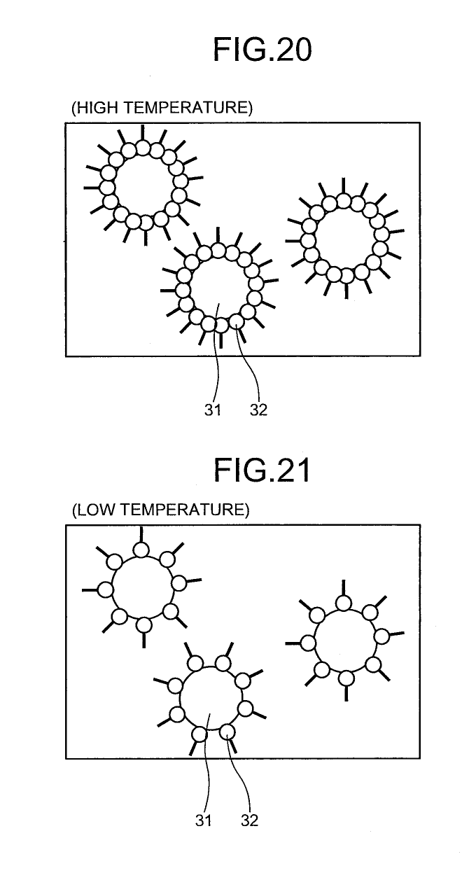

FIG. 20 is a schematic diagram of an adsorption state of cerium oxide particles and anionic surfactants when the polishing slurry containing the cerium oxide particles and the anionic surfactants has a high temperature. FIG. 21 is a schematic diagram of an adsorption state of cerium oxide particles and anionic surfactants when the polishing slurry containing the cerium oxide particles and the anionic surfactants has a lower temperature. As shown in FIG. 20, when the polishing slurry has a high temperature, many anionic surfactants are firmly adsorbed to the cerium oxide particles, and are conglomerated. On the other hand, as shown in FIG. 21, when the polishing slurry has a low temperature, a state of adsorption of the anionic surfactants to the cerium oxide particles is suppressed, and the number of anionic surfactants adsorbed to the cerium oxide particles decreases as compared with the number when the polishing slurry has a high temperature.

Accordingly, when the polishing slurry has a low temperature, the surface protection effect of the anionic surfactants on the abrasive grains (the cerium oxide particles) decreases as compared with the effect when the polishing slurry has a high temperature. Consequently, a reduction of the convexity polishing speed as high polishing speed can be suppressed. As a result, a reduction of the selection ratio of the polishing speed in the convexities 13 and the polishing speed in the concavities 14 can be suppressed, and aggravation of the planarization characteristic can be prevented.

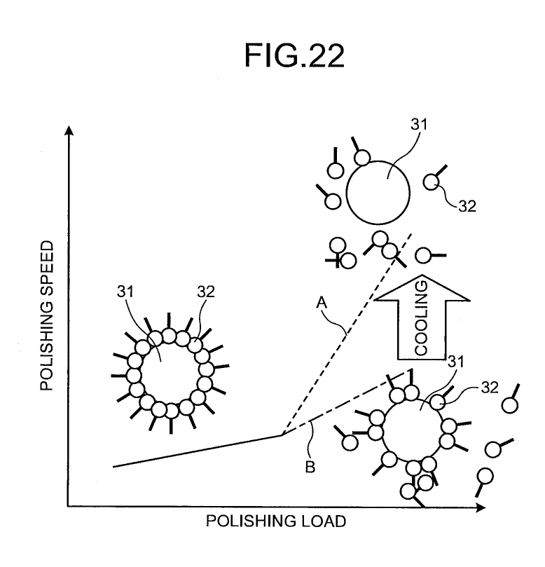

FIG. 22 depicts an example of characteristics of a change of a relationship between a polishing load and polishing speed due to a polishing slurry temperature in the CMP process performed on a silicon oxide film using a polishing slurry containing the cerium oxide particles and the anionic surfactants. In FIG. 22, a line A represents a characteristic when a polishing slurry temperature is decreased by cooling the polishing slurry after a predetermined polishing load. A line B represents a characteristic when the polishing slurry is not cooled.

As shown in FIG. 22, when the polishing slurry temperature is lowered by cooling the polishing slurry (the line A), the polishing speed greatly increases along the increase of the polishing load. On the other hand, when the polishing slurry temperature is not lowered (the line B), the polishing speed also increases along the increase of the polishing load. However, the polishing speed does not increase at a higher rate than that when the polishing slurry temperature is lowered (the line A). Therefore, when the silicon oxide film is planarized by the CMP method at the same polishing load, higher polishing speed can be obtained by lowering the polishing slurry temperature. This effect becomes more significant when the polishing load becomes higher.

Accordingly, it is possible to suppress a reduction of the selection ratio of the polishing speed in the convexities 13 and the polishing speed in the concavities 14 due to the agglomeration of the cerium oxide particles and the anionic surfactants attributable to the rise in the temperature of the polishing slurry by lowering the polishing slurry temperature at the polishing time. Based on the synergy effect of this suppression and the concavity protection effect obtained by adding the resin particles having a cationic surface functional group to the polishing slurry, the selection ratio of the polishing speed in the convexities 13 and the polishing speed in the concavities 14 is improved significantly, and the planarization effect can be improved.

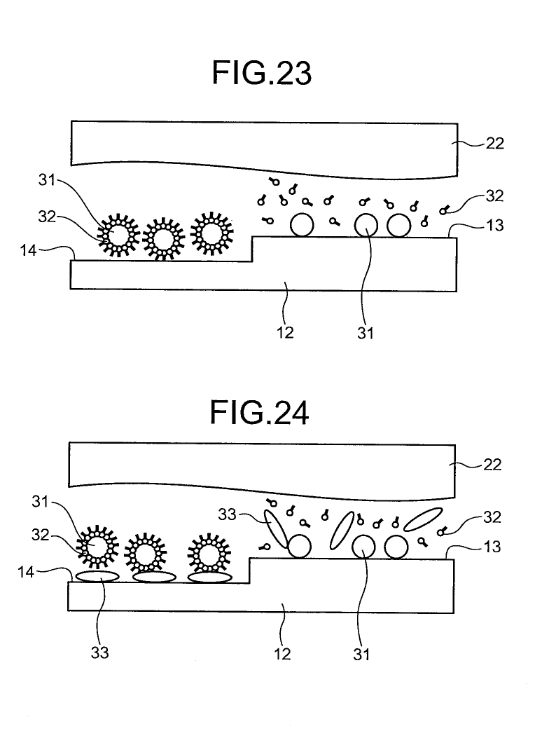

FIG. 23 is a schematic diagram of a concavity protection state when the conventional polishing slurry containing the cerium oxide particles 31 and the anionic surfactants 32 is used. FIG. 24 is a schematic diagram of a concavity protection state when a polishing slurry containing the cerium oxide particles 31, the anionic surfactants 32, and the resin particles 33 having a cationic surface functional group is used.

When the polishing slurry containing the cerium oxide particles 31 and the anionic surfactants 32 is used, as shown in FIG. 23, in the region of a small polishing load, that is, in the concavities 14 of the silicon oxide film 12, an effect of selectively protecting the concavities 14 is obtained based on the adsorption of the anionic surfactants 32 to the cerium oxide particles 31 and the agglomeration. The adsorption of the anionic surfactants 32 to the cerium oxide particles 31 has load dependency. Therefore, in a region of a large polishing load, that is, in the convexities 13 of the silicon oxide film 12, the state of adsorption of the anionic surfactants 32 to the cerium oxide particles 31 is mitigated. A number of the anionic surfactants 32 adsorbed to the cerium oxide particles 31 decreases more than that in the concavities 14 of the silicon oxide film 12. Consequently, in the convexities 13, the polishing speed increases more than that in the concavities 14. By increasing the selection ratio of the polishing speed in the convexities 13 and the polishing speed in the concavities 14, the planarization characteristic is improved.

When the polishing slurry containing the cerium oxide particles 31, the anionic surfactants 32, and the resin particles 33 having a cationic surface functional group is used, as shown in FIG. 24, in the region of a small polishing load, that is, in the concavities 14 of the silicon oxide film 12, an effect of selectively protecting the concavities 14 is obtained based on the adsorption of the anionic surfactants 32 to the cerium oxide particles 31 and the agglomeration. Further, an effect of selectively protecting the concavities 14 is obtained by adsorbing the resin particles 33 having a cationic surface functional group to the silicon oxide film 12.

On the other hand, in the region of a large polishing load, that is, in the convexities 13 of the silicon oxide film 12, a state of adsorption of the anionic surfactants 32 to the cerium oxide particles 31 is mitigated, in a similar manner to that shown in FIG. 23. The adsorption of the resin particles 33 having a cationic surface functional group to the silicon oxide film 12 has load dependency, like the adsorption of the anionic surfactants 32 to the cerium oxide particles 31, and the adsorption state changes depending on load. That is, in the region of a large polishing load, or in the convexities 13, a state of adsorption of the resin particles 33 having a cationic surface functional group to the silicon oxide film 12 is mitigated. A number of the resin particles 33 having a cationic surface functional group adsorbed to the silicon oxide film 12 decreases more than that in the concavities 14. Consequently, in the convexities 13, the polishing speed increases more than that in the concavities 14. A selection ratio of the polishing speed in the convexities 13 and the polishing speed in the concavities 14 is increased, and flatness of the silicon oxide film 12 can be improved.

In the second embodiment, a rise in the temperature of the polishing slurry is suppressed by decreasing the content (concentration: wt %) of the cerium oxide particles in the polishing slurry, for example. When the content (concentration: wt %) of the cerium oxide particles in the polishing slurry is decreased, the amount of cerium oxide particles present between the polishing pad and the silicon oxide film at the polishing time decreases. Accordingly, the polishing action between the silicon oxide film, the abrasive grains (the cerium oxide particles), and the polishing pad is suppressed, thereby decreasing the frictions between the silicon oxide film, the abrasive grains (the cerium oxide particles), and the polishing pad. Consequently, a rise in the temperature of the polishing slurry can be suppressed.

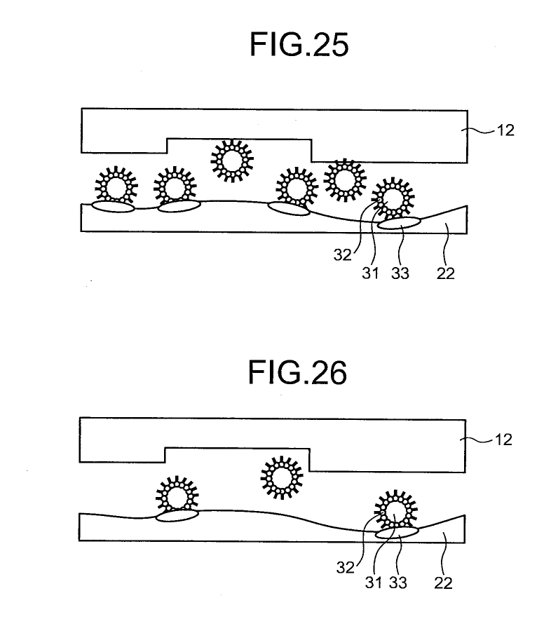

FIG. 25 is a schematic diagram for explaining a state between the silicon oxide film 12 and the polishing pad 22 in the CMP process using a polishing slurry having a large content (high concentration) of the cerium oxide particles 31. FIG. 26 is a schematic diagram for explaining a state between the silicon oxide film 12 and the polishing pad 22 in the CMP process using a polishing slurry having a small content (low concentration) of the cerium oxide particles 31. The above polishing slurries contain the cerium oxide particles 31, the anionic surfactants 32, and the resin particles 33 having a cationic surface functional group.

As shown in FIG. 25, when the polishing slurry contains a large amount of the cerium oxide particles 31, the amount of the cerium oxide particles 31 present between the silicon oxide film 12 and the polishing pad 22 becomes large. On the other hand, as shown in FIG. 26, when the polishing slurry contains a small amount of the cerium oxide particles 31, the amount of the cerium oxide particles 31 present between the silicon oxide film 12 and the polishing pad 22 becomes small. Therefore, when the content of the cerium oxide particles 31 in the polishing slurry is decreased, the polishing action between the silicon oxide film 12, the cerium oxide particles 31, and the polishing pad 22 can be suppressed. By decreasing the frictions between the silicon oxide film 12, the cerium oxide particles 31, and the polishing pad 22, a rise in the temperature of the polishing slurry can be suppressed.

In the CMP method using the polishing slurry containing the cerium oxide particles, the anionic surfactants, and the resin particles having a cationic surface functional group, a rise in the temperature of the polishing slurry can be suppressed by particularly setting the content (concentration) of the cerium oxide particles in the polishing slurry to equal to or higher than 0.05 wt % and equal to or lower than 0.3 wt %. When the content (concentration) of the cerium oxide particles in the polishing slurry is set equal to or lower than 0.3 wt %, an effect of decreasing the frictions between the silicon oxide film 12, the cerium oxide particles 31, and the polishing pad 22 becomes large, and a more satisfactory flatness characteristic can be obtained. When the concentration of the cerium oxide particles 31 is lower than 0.05 wt %, the polishing speed becomes low.

As a method of suppressing a rise in the temperature of the polishing slurry in the polishing by the CMP method, there is a method of increasing a supply amount of the polishing slurry to the polishing pad during the polishing. When the supply amount of the polishing slurry to the polishing pad is increased during the polishing, it takes a shorter time to replace the polishing slurry of which temperature is high due to the polishing with a polishing slurry of which temperature is not high, on the polishing pad. Accordingly, by decreasing the temperature of the polishing slurry on the polishing pad, a rise in the temperature of the polishing slurry can be suppressed.

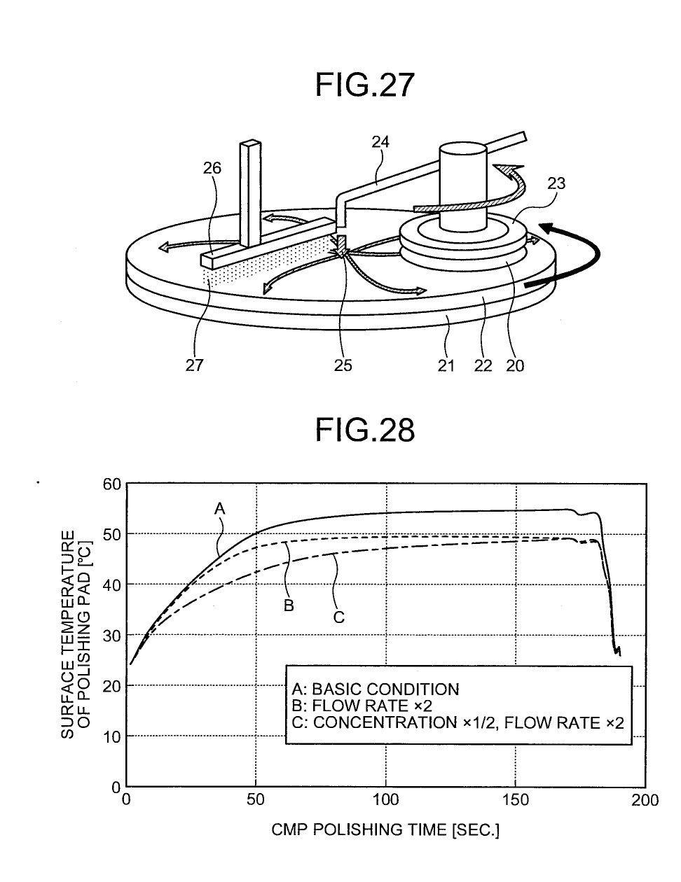

Further, as a method of suppressing a rise in the temperature of the polishing slurry in the polishing by the CMP method, there is a method of supplying a gas 27 onto the polishing pad 22 through a gas supply tube 26 as shown in FIG. 27. FIG. 27 is a schematic diagram of an overall configuration of a polishing device that performs the CMP process on the silicon oxide film by suppressing a rise in the temperature of the polishing slurry. When the gas 27 is supplied onto the polishing pad 22 during the polishing by the CMP method, a rise in the temperature of a polishing slurry 25 supplied to the polishing pad 22 can be suppressed. The gas supplied onto the polishing pad 22 is not particularly limited, and air, nitrogen or the like can be used.

FIG. 28 depicts an example of surface temperature characteristics of a polishing pad in the CMP process performed on a silicon oxide film using a polishing slurry containing the cerium oxide particles, the anionic surfactants, and the resin particles having a cationic surface functional group. In FIG. 28, the lateral axis represents a CMP polishing time (second), and the vertical axis represents a surface temperature (° C.) of the polishing pad. During the polishing, a temperature of the polishing slurry also increases in a similar pattern to that of the surface temperature (° C.) of the polishing pad along the increase in the surface temperature (° C.) of the polishing pad. Therefore, the surface temperature (° C.) of the polishing pad is shown here.

In FIG. 28, a curve A corresponds to the following basic condition (condition A), a curve B corresponds to a condition (condition B) that a flow rate (supply amount) of the polishing slurry in the basic condition is doubled, and a curve C corresponds to a condition (condition C) that a flow rate (supply amount) of the polishing slurry in the basic condition is doubled and that abrasive grain concentration of the polishing slurry is halved.

### (Basic Condition: Condition A)

### <Polishing Slurry>

The polishing slurry used contained cerium oxide particles and anionic surfactants in pure water, and resin particles having a cationic surface functional group. An adjustment condition of the polishing slurry was as follows.

### [Cerium Oxide]

Cerium oxide used for the abrasive grains was DLS2 (primary particle diameter 100 nanometers) manufactured by Hitachi Chemical Co., Ltd. This cerium oxide was contained in concentration of 0.5 wt % into the polishing slurry.

### [Anionic Surfactants]

As ammonium polycarboxylate, TK75 (molecular weight 6,000) manufactured by Kao Corporation was used. This ammonium polycarboxylate was contained in concentration of 0.7 wt % into the polishing slurry.

### [Resin Particles Having Cationic Surface Functional Group]

Polystyrene (PST, average particle diameter: 160 nanometers) having the amino group manufactured by JSR Corporation was used. This polystyrene was contained in concentration of 0.1 wt % into the polishing slurry.

### <Polishing Pad>

IC1000/Suba 400 (modulus of elasticity 300 megapascals) manufactured by Rohm and Haas Company was used.

### <Table Rotation Number>

100 rpm

### <Polishing Pressure>

300 hectopascals

### <Polishing Time>

180 seconds

### <Slurry Flow Rate>

190 cc/min.

### <Polishing Sample>

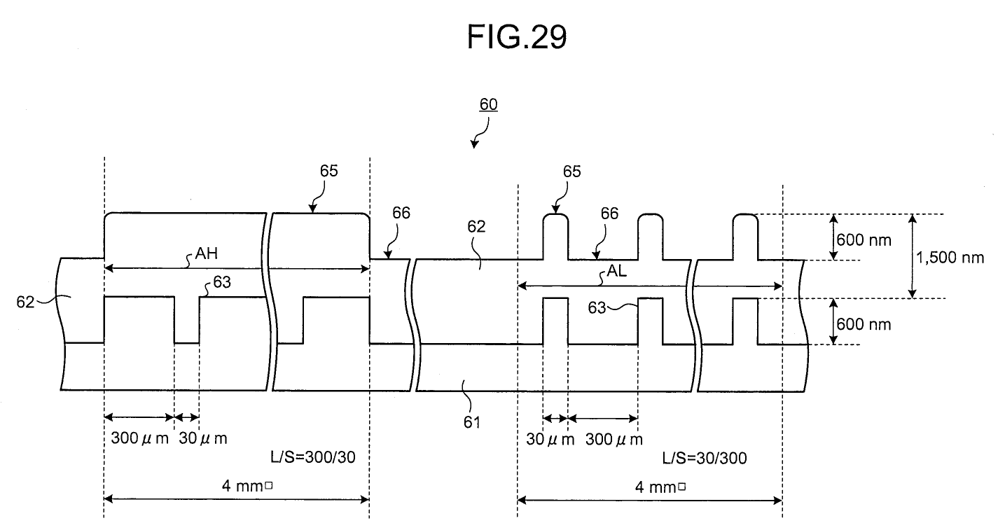

A polishing sample 60 having a pattern shown in FIG. 29 was used. FIG. 29 is a schematic diagram for explaining the polishing sample 60. The polishing sample 60 shown in FIG. 29 was manufactured as follows. First, steps 63 having the height of 600 nanometers were formed on a silicon substrate 61 by the normal lithography method and the normal dry etching method. A size of line and space of the steps 63 was changed to form a pattern having a large area of a region AH in the high convexity coverage (90%) and a region AL in the low convexity coverage (10%). The region AH and the region AL had an area of 4 mm×4 mm, respectively. A silicon oxide film (SiO₂ film) 62 was formed in a thickness of 1,500 nanometers on the silicon substrate 61 by the CVD method, thereby manufacturing the polishing sample 60. Convexities 65 and concavities 66 were formed on the silicon oxide film 62.

As shown in FIG. 28, a highest temperature of a surface of the polishing pad in the polishing by the CMP method is 55° C. in the basic condition (the condition A), and is approximately 50° C. in the condition B that the flow rate (supply amount) of the polishing slurry in the basic condition is doubled. As explained above, when the flow rate (supply amount) of the polishing slurry is increased, a rise in the temperature of the surface of the polishing pad in the polishing by the CMP method can be suppressed. That is, a rise in the temperature of the polishing slurry on the polishing pad can be suppressed. Accordingly, a reduction in the selection ratio of the polishing speed in the region AH and the polishing speed in the region AL attributable to a rise in the temperature of the polishing slurry can be suppressed, and the planarization characteristic can be improved.

In the condition C that a flow rate (supply amount) of the polishing slurry in the basic condition is doubled and that abrasive grain concentration of the polishing slurry is halved, a highest temperature of the surface of the polishing pad in the polishing by the CMP method is approximately 49° C. As shown in FIG. 28, while the highest temperature of the surface of the polishing pad is approximately equal to that in the condition B, a rise until when the temperature reaches the highest temperature is slow. That is, in the condition C, a time required to reach the highest temperature is longer than that in the condition B. As explained above, when the flow rate (supply amount) of the polishing slurry is increased from the basic condition and also when the abrasive grain concentration of the polishing slurry is decreased, a rise in the highest temperature of the surface of the polishing pad in the polishing by the CMP method can be suppressed. Further, a time required for the surface temperature of the polishing pad to reach the highest temperature can be set long. That is, a rise in the temperature of the polishing slurry on the polishing pad in the polishing by the CMP method can be suppressed, and a time required for the temperature of the polishing slurry on the polishing pad to reach the highest temperature can be set long. Accordingly, a reduction in the selection ratio of the polishing speed in the region AH and the polishing speed in the region AL attributable to a rise in the temperature of the polishing slurry can be more suppressed, and the planarization characteristic can be more improved.

Therefore, according to the semiconductor device manufacturing method in the second embodiment, when the content (concentration) of the cerium oxide particles in the polishing slurry containing the cerium oxide particles, the anionic surfactants, and the resin particles having a cationic surface functional group is set equal to or higher than 0.05 wt % and equal to or lower than 0.3 wt %, aggravation of the polishing characteristic attributable to a rise in the temperature of the polishing slurry can be suppressed, a selection ratio of the polishing speed in the convexities and the polishing speed in the concavities of the silicon oxide film can be improved, and an excellent planarization characteristic can be stably obtained. Based on the synergy effect of the above and the concavity protection effect obtained by adding the resin particles having a cationic surface functional group to the polishing slurry, the selection ratio of the polishing speed in the convexities and the polishing speed in the concavities 14 is more improved, and the planarization effect can be improved. When the CMP process is performed in a condition that the polishing pressure is within a range of 50 to 200 hectopascals and that the rotation number of the polishing pad is within the range of 10 to 80 rpm in a state that the polishing slurry is supplied onto the polishing pad having a modulus of elasticity within a range of 400 to 600 megapascals, the selection ratio of the polishing speed in the convexities and the polishing speed in the concavities is further improved, and the planarization characteristic can be improved, based on the synergy effect of the above effect and a suppression effect of elastic deformation of the polishing pad.

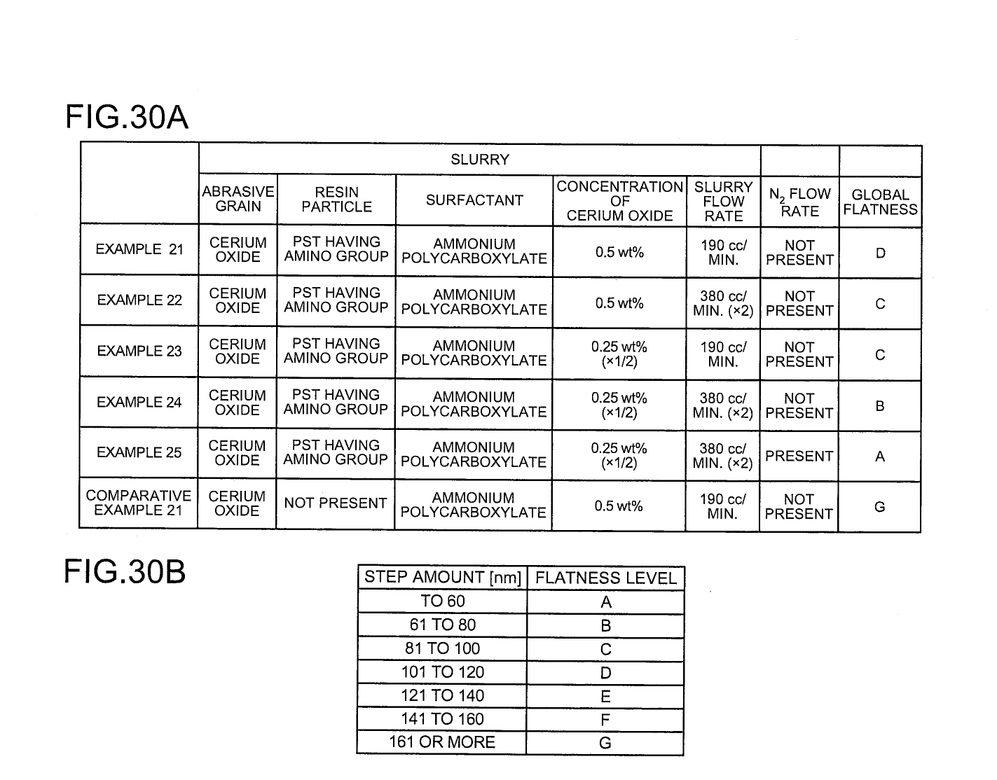

The semiconductor device manufacturing method according to the second embodiment is explained below with reference to detailed examples. The polishing sample 60 having a pattern as shown in FIG. 29 was polished until when a polishing amount of the concavities 66 became about 100 to 200 nanometers by the CMP method using the polishing device shown in FIG. 27, thereby planarizing the pattern of the silicon oxide film (SiO₂ film). A detailed CMP processing condition (basic condition) was as follows. A slurry condition and a slurry cooling condition are shown together in FIG. 30A.

### <Polishing Slurry>

The polishing slurry used contained cerium oxide particles and anionic surfactants in pure water, and resin particles having a cationic surface functional group. An adjustment condition of the polishing slurry was as follows.

### [Cerium Oxide]

Cerium oxide used for the abrasive grains was DLS2 (primary particle diameter 100 nanometers) manufactured by Hitachi Chemical Co., Ltd. This cerium oxide was contained in concentration of 0.5 wt % into the polishing slurry.

### [Anionic Surfactants]

As ammonium polycarboxylate, TK75 (molecular weight 6,000) manufactured by Kao Corporation was used. This ammonium polycarboxylate was contained in concentration of 0.7 wt % into the polishing slurry.

### [Resin Particles Having Cationic Surface Functional Group]

Polystyrene (PST, average particle diameter: 160 nanometers) having the amino group manufactured by JSR Corporation was used. This polystyrene was contained in concentration of 0.1 wt % into the polishing slurry.

### <Polishing Pad>

IC1000/Suba 400 (modulus of elasticity 300 megapascals) manufactured by Rohm and Haas Company was used.

### <Table Rotation Number>

100 rpm

### <Polishing Pressure>

300 hectopascals

### <Polishing Time>

180 seconds

### <Slurry Flow Rate>

190 cc/min.

The polishing sample was CMP processed in each condition of Example 21 to Example 25 of the second embodiment and Comparative example 21 to be compared. Classifications of these examples and the comparative example were as follows.

### Example 21

The basic condition.

### Example 22

The flow rate of the polishing slurry in the basic condition was changed to double (380 cc/min.).

### Example 23

The concentration of cerium oxide particles in the polishing slurry in the basic condition was changed to half (0.25 wt %).

### Example 24

The concentration of cerium oxide particles in the polishing slurry in the basic condition was changed to half (0.25 wt %), and the flow rate of the polishing slurry in the basic condition was changed to double (380 cc/min.).

### Example 25

The concentration of cerium oxide particles in the polishing slurry in the basic condition was changed to half (0.25 wt %), and the flow rate of the polishing slurry in the basic condition was changed to double (380 cc/min.). Further, the polishing slurry was cooled by injecting a nitrogen (N₂) gas to the polishing pad during a polishing.

### Comparative Example 21

The resin particles having a cationic surface functional group in the polishing slurry are not used in the basic condition.

FIG. 30A depicts step amounts (global flatness) of the convexities 65 and the concavities 66 by dividing the step amount into levels A to G, as a CMP processing result in Example 21 to Example 25 and Comparative example 21. The levels of the global flatness are classified into seven from A to G corresponding to the step amount (nanometers) of the convexities 65 and the concavities 66. Among the seven levels, the level A has a smallest step amount, and has satisfactory global flatness. FIG. 30B depicts a classification of the levels of the global flatness.

As is understood from FIGS. 30A and 30B, in Example 21 as the basic condition, the level of the global flatness is more satisfactory than that in Comparative example 21 that does not use the resin particles having a cationic surface functional group in the polishing slurry in the basic condition. Accordingly, an improvement effect of the global flatness is recognized as a result of containing the resin particles having a cationic surface functional group into the polishing slurry containing the cerium oxide particles and the anionic surfactants.

As Example 21 is compared with Example 22, Example 22 that changes the flow rate of the polishing slurry in the basic condition to double has a more satisfactory level of the global flatness than that of Example 21. Accordingly, an improvement effect of the global flatness is recognized as a result of suppressing a rise in the temperature of the polishing slurry by increasing the flow rate of the polishing slurry.

As Example 21 is compared with Example 23, Example 23 that changes the concentration of the cerium oxide particles in the polishing slurry to half of that in the basic condition and that changes the content (concentration) of the cerium oxide particles in the polishing slurry to 0.3 wt % or lower has a more satisfactory level of the global flatness than that of Example 21. Accordingly, an improvement effect of the global flatness is recognized as a result of suppressing a rise in the temperature of the polishing slurry by decreasing the concentration of the cerium oxide particles in the polishing slurry to 0.3 wt % or lower.

As Example 22 and Example 23 are compared with Example 24, Example 24 has a more satisfactory level of the global flatness than that of Example 22 and Example 23. Accordingly, a further improvement effect of the global flatness is recognized as a result of both increasing the flow rate of the polishing slurry and decreasing the concentration of the cerium oxide particles in the polishing slurry.

As Example 24 is compared with Example 25, Example 25 has a more satisfactory level of the global flatness than that of Example 24. Accordingly, a further improvement effect of the global flatness is recognized as a result of cooling the polishing slurry by injecting the nitrogen (N2) gas during the polishing, by both increasing the flow rate of the polishing slurry and decreasing the concentration of the cerium oxide particles in the polishing slurry.

Therefore, it is safe to say from the above result that in the CMP process performed on the polishing sample 60 using the polishing slurry containing the cerium oxide particles, the anionic surfactants, and the resin particles having a cationic surface functional group, the following improvement effects of the global flatness are recognized: the improvement effect of the global flatness by increasing the flow rate of the polishing slurry; the improvement effect of the global flatness by setting the content (concentration) of the cerium oxide particles in the polishing slurry to 0.3 wt % or lower; and the improvement effect of the global flatness by injecting the nitrogen (N₂) gas to the polishing pad during the polishing.

### Third Embodiment

Generally, in performing a planarizing process by the CMP method to a substance to be polished made of a silicon oxide film (SiO₂ film), a dressing process is performed on the surface of a polishing pad before performing a polishing. As explained in the first embodiment, when a polishing pad of a high modulus of elasticity (high hardness) is used and also when a polishing pressure and a rotation number of the polishing pad are set to low values, a surface state of a surface layer of the polishing pad (hereinafter, simply “surface layer”) after the dressing process is performed also receives a large influence in the polishing characteristic. Therefore, in the dressing process, it is important to set the surface of the surface layer to a state suitable for the polishing. However, particularly when a polishing pad of a high modulus of elasticity (high hardness) is used, the surface of the surface layer after the dressing process is not always kept in a proper state for the polishing, and desired polishing speed and a desired flatness characteristic cannot be obtained because a polishing slurry cannot be held.

In the dressing process performed on the polishing pad, an obtained surface state of the surface layer changes by changing a kind of a dresser and a dressing condition. Consequently, a modulus of elasticity of the surface layer and a depth of the surface layer change. When the surface state of the surface layer is deviated from a predetermined proper range, the polishing by the CMP method has a risk of the occurrence of a problem.

In a third embodiment of the present invention, aggravation of the polishing characteristic attributable to a surface state of the surface layer is suppressed and a flatness characteristic is improved, by adjusting the modulus of elasticity of the surface layer formed by the dressing process and by adjusting a depth (thickness) of the surface layer so that the surface layer of the front layer becomes in a proper state for the planarizing process of the polished substance made of a silicon oxide film (SiO₂ film).

In the third embodiment, the dressing process is performed so that the surface layer after the dressing process has a depth (thickness) within a range of 20 to 100 micrometers from the surface of the polishing pad and that the modulus of elasticity becomes low, equal to or higher than 50 megapascals and lower than 400 megapascals. The planarizing process is performed on the silicon oxide film (SiO₂ film) by the CMP process using the cerium oxide particles and the anionic surfactants. When the surface layer after the dressing process satisfies this condition, the surface layer can properly hold polishing abrasive grains giving an influence to the polishing characteristic, and a contact area between the polishing pad and a polished surface of the silicon oxide film (SiO₂ film) can be sufficiently secured. Consequently, a satisfactory polishing characteristic can be stably obtained.

When the surface layer has a too shallow depth (less than 20 micrometers), scratch on the polished surface increases. The effect of keeping the surface layer in a low modulus of elasticity cannot be sufficiently obtained, and it becomes difficult to properly hold the polishing abrasive grain (cerium oxide particles) on the surface layer. A contact area between the polishing pad and a polished surface of the silicon oxide film (SiO₂ film) cannot be sufficiently secured. On the other hand, when a portion of a low modulus of elasticity has a too deep depth (larger than 100 micrometers), a polishing characteristic is not so different from that when a whole portion of a used polishing pad has a low modulus of elasticity. Dishing in the polishing becomes large, and the global flatness is aggravated.

When the modulus of elasticity of the surface layer is too low (lower than 50 megapascals), dishing in the polishing becomes large, and the global flatness is aggravated. On the other hand, when the modulus of elasticity of the surface layer is too high (equal to or higher than 400 megapascals), the modulus of elasticity becomes close to a bulk modulus of elasticity. Consequently, the function of the surface layer cannot be sufficiently performed, and the surface layer cannot properly hold the polishing abrasive grains. Further, a contact area between the polishing pad and the polished surface of the polished substance cannot be sufficiently secured.

There is a certain level of correlation between a modulus of elasticity and a depth of the surface layer. When a polishing pad has a bulk modulus of elasticity within a range of 400 to 600 megapascals, the modulus of elasticity of the surface layer often becomes equal to or higher than 400 megapascals when the depth of the surface layer is smaller than 20 micrometers. When the depth of the surface layer exceeds 100 micrometers, the modulus of elasticity of the surface layer often becomes lower than 50 megapascals.

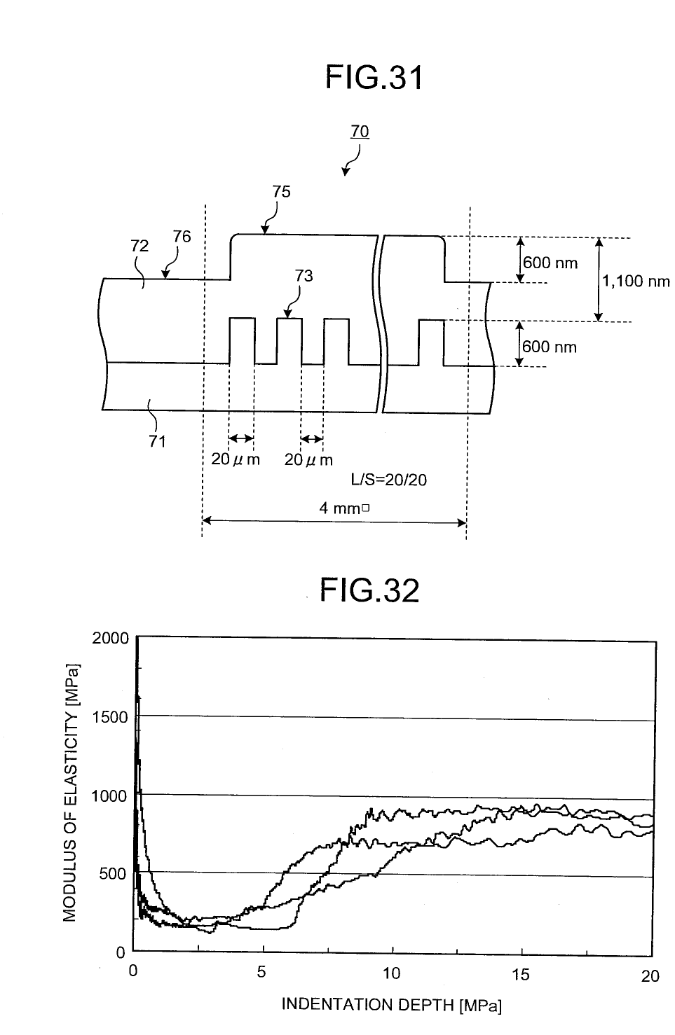

FIG. 31 is a schematic diagram for explaining a polishing sample 70 according to the third embodiment. As shown in FIG. 31, a step 73 having the height of 600 nanometers was formed on a silicon substrate 71 by the normal lithography method and the normal dry etching method as shown in FIG. 31. A pattern having a 4 mm×4 mm area having a line and space size of the step 73 as L/S=20 μm/20 μm was formed. A silicon oxide film (SiO₂ film) was formed in a thickness of 1100 nanometers on the silicon substrate 71 by the CVD method, thereby manufacturing the polishing sample 70. A large area of convexities 75 and concavities 76 was formed on a silicon oxide film 72.

The polishing sample 70 was polished until when a polishing amount of the concavities 76 by the CMP method using the polishing device shown in FIG. 2 became about 100 nanometers, thereby planarizing the pattern of the silicon oxide film (SiO₂ film). CMP processing conditions were as follows.

### <Polishing Slurry>

The polishing slurry used contained cerium oxide particles and anionic surfactants in pure water. An adjustment condition of the polishing slurry was as follows.

### [Cerium Oxide]

Cerium oxide used for the abrasive grains was DLS2 (primary particle diameter 100 nanometers) manufactured by Hitachi Chemical Co., Ltd. This cerium oxide was contained in concentration of 0.5 wt % into the polishing slurry.

### [Anionic Surfactants]

As ammonium polycarboxylate, TK75 (molecular weight 6,000) manufactured by Kao Corporation was used. This ammonium polycarboxylate was contained in concentration of 0.7 wt % into the polishing slurry.

### <Table Rotation Number>

60 rpm

### <Polishing Pressure>

150 hectopascals

In such CMP processing conditions, a planarizing process was performed by a polishing pad having a bulk modulus of elasticity within a range of 400 to 600 megapascals, and a modulus of elasticity of the surface layer lower than 50 megapascals. As a result, a dishing amount in the large area of the convexities 75 after the polishing became larger than 100 nanometers. On the other hand, when a planarizing process was performed by a polishing pad having a bulk modulus of elasticity within a range of 400 to 600 megapascals, and a modulus of elasticity of the surface layer equal to or higher than 50 megapascals and lower than 400 megapascals, a dishing amount in the large area of the convexities 75 after the polishing became smaller than 40 nanometers.

FIG. 32 depicts an example of characteristics of a relationship between an indentation depth and a modulus of elasticity of a polishing pad having a surface layer with a depth (thickness) from the surface of the polishing pad within the range of 20 to 100 micrometers and a modulus of elasticity equal to or higher than 50 megapascals and lower than 400 megapascals. Data in FIG. 32 are a result of measuring at three points of the polishing pad by the nanoindenter method. The polishing pad used was NCP-1 (bulk modulus of elasticity 550 megapascals) manufactured by Nihon Micro Coating Co., Ltd. A dressing process was performed in the condition of a load 100 newton and a dressing time 30 seconds, using the diamond dresser (M-100C) manufactured by Asahi Diamond Industrial Co., Ltd. A surface layer (portion of a low modulus of elasticity) having a lower modulus of elasticity than that of the bulk was formed on the surface of the polishing pad. The data in FIG. 32 are a result of measuring at three points of the polishing pad by the nanoindenter method. It can be understood that the surface layer satisfying the condition of the portion of a low modulus of elasticity is formed. Based on the characteristic of the nanoindenter method, a ten times of the measured value of the indentation depth becomes a depth of performance. Accordingly, an indentation depth position of 5 micrometers in FIG. 32 is actually a depth position of 50 micrometers.

A semiconductor device manufacturing method according to the third embodiment is explained below with reference to detailed examples. First, an example concerning a depth of the surface layer of the polishing pad is explained.

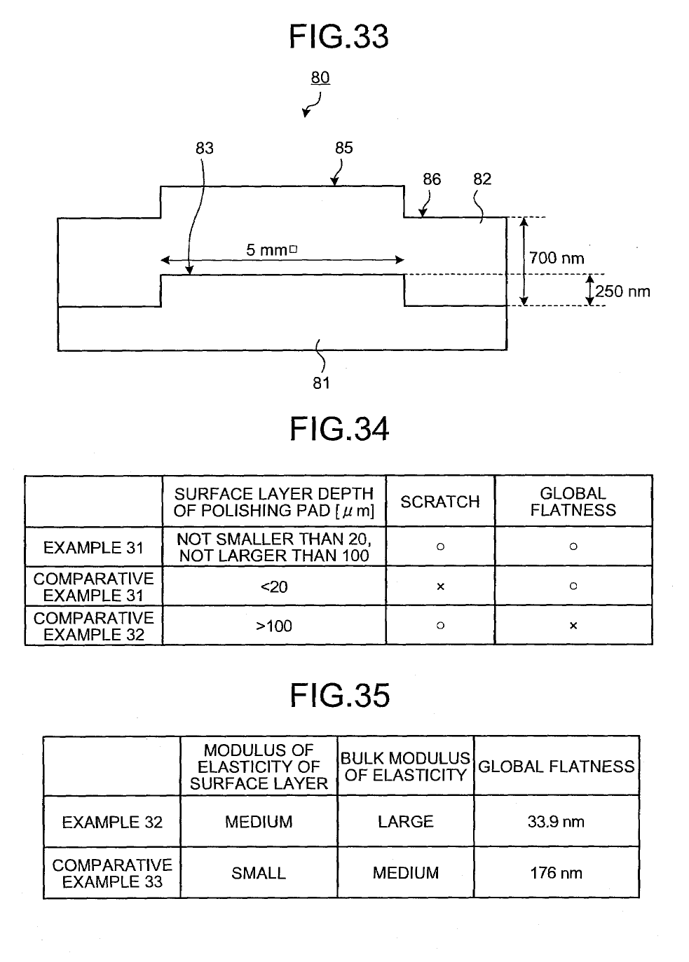

FIG. 33 is a schematic diagram for explaining a polishing sample 80 used here. As shown in FIG. 33, a step 83 having a height 250 nanometers was formed on a silicon substrate 81 by the normal lithography method and the normal dry etching method as shown in FIG. 33, thereby forming a pattern having a 5 mm×5 mm. A silicon oxide film (SiO₂ film) 82 was formed on this silicon substrate 81 by the CVD method, thereby manufacturing the polishing sample 80. Convexities 85 and concavities 86 were formed on the silicon oxide film 82.

The polishing sample 80 was polished until when a polishing amount of the concavities 86 by the CMP method using the polishing device shown in FIG. 2 became about 100 nanometers, thereby planarizing the pattern of the silicon oxide film (SiO₂ film). Detailed CMP processing conditions were as follows.

### <Polishing Slurry>

The polishing slurry used contained cerium oxide particles and anionic surfactants in pure water. An adjustment condition of the polishing slurry was as follows.

### [Cerium Oxide]

Cerium oxide used for the abrasive grains was DLS2 (primary particle diameter 100 nanometers) manufactured by Hitachi Chemical Co., Ltd. This cerium oxide was contained in concentration of 0.5 wt % into the polishing slurry.

### [Anionic Surfactants]

As ammonium polycarboxylate, TK75 (molecular weight 6,000) manufactured by Kao Corporation was used. This ammonium polycarboxylate was contained in concentration of 0.7 wt % into the polishing slurry.

### <Polishing Pad>

NCP-1 (bulk modulus of elasticity 550 megapascals) manufactured by Nihon Micro Coating Co., Ltd. was used. A dressing process was performed by adjusting a load and a dressing time using the diamond dresser (M-100C) manufactured by Asahi Diamond Industrial Co., Ltd.

### <Table Rotation Number>

60 rpm

### <Polishing Pressure>

150 hectopascals

The CMP process was performed on the polishing sample 80 in each condition of Example 31 of the third embodiment and in Comparative example 31 and Comparative example 32 to be compared. Examples and comparative examples were classified as follows.

### Example 31

A polishing pad having a surface layer with a depth (thickness) from the surface of the polishing pad within the range of 20 to 100 micrometers was used.

### Comparative Example 31

A polishing pad having a surface layer with a depth (thickness) from the surface of the polishing pad smaller than 20 micrometers was used.

### Comparative Example 32

A polishing pad having a surface layer with a depth (thickness) from the surface of the polishing pad larger than 100 micrometers was used.

FIG. 34 depicts a result of evaluating a scratch occurrence state and a global flatness on the polished surface of the polishing sample 80 after the CMP process. In FIG. 34, for the evaluation of the scratch occurrence state, “x” represents the occurrence of scratch on the polished surface, and “O” represents the non-occurrence of scratch on the polished surface. For the global flatness, “O” represents a case that a global step (a step between the convexities 85 and the concavities 86) is equal to or smaller than 40 nanometers, and “x” represents a case that the global step is larger than 40 nanometers.

As is understood from FIG. 34, in Example 31, there is no scratch on the polished surface, and the global flatness is equal to or smaller than 40 nanometer, with a satisfactory result. From this result, it is recognized that a satisfactory flatness characteristic is obtained by the polishing pad having a surface layer with a depth (thickness) from the surface layer within the range of 20 to 100 micrometers.

As Example 31, Comparative example 31, and Comparative example 32 are compared with each other, there is no scratch on the polished surface, and the global flatness is equal to or smaller than 40 nanometer, with a satisfactory result in Example 31. On the other hand, scratch occurs in Comparative example 31. In Comparative example 32, the global step is larger than 40 nanometers, and the global flatness decreases.

Therefore, it is safe to say from the above result that in the CMP process performed on the polishing sample 80 using the polishing slurry containing the cerium oxide particles and the anionic surfactants, an improvement effect of the planarization characteristic is recognized by using the polishing pad of a high modulus of elasticity (high hardness) having a surface layer with a depth (thickness) from the surface within the range of 20 to 100 micrometers and by setting the polishing pressure and the rotation number of the polishing pad to low values.

Examples concerning a modulus of elasticity of the surface layer of the polishing pad are explained next. The polishing sample 80 was polished until when a polishing amount of the concavities 86 by the CMP method using the polishing device shown in FIG. 2 became about 100 nanometers, thereby planarizing the pattern of the silicon oxide film (SiO₂ film). A detailed CMP processing condition was as follows.

### <Polishing Slurry>

The polishing slurry used was adjusted in exactly the same condition as that of Example 31, Comparative example 31, and Comparative example 32.

### <Polishing Pad>

A dressing process was performed by adjusting a load and a dressing time using the diamond dresser (M-100C) manufactured by Asahi Diamond Industrial Co., Ltd.

### <Table Rotation Number>

60 rpm

### <Polishing Pressure>

150 hectopascals

The CMP process was performed on the polishing sample 80 in each condition of Example 32 of the third embodiment, and Comparative example 33 to be compared. The example and the comparative example were classified as follows. Levels of a modulus of elasticity c described below were set as follows; Level “small”: c<50 megapascals, level “medium”: 50 megapascals ≦c<400 megapascals, and level “large”: 400 megapascals ≦c≦600 megapascals.

### Example 32

A dressing process was performed on NCP-2 manufactured by Nihon Micro Coating Co., Ltd. in the condition of a load 100 newton and the dressing time 30 seconds. A dressing pad having the level “medium” for the modulus of elasticity of the surface layer and having the level “large” for the bulk modulus of elasticity was used.

### Comparative Example 33

A dressing process was performed on IC1000/Suba 400 manufactured by Rohm and Haas Company in the condition of a load 200 newton and the dressing time 30 seconds. A dressing pad having the level “small” for the modulus of elasticity of the surface layer and having the level “medium” for the bulk modulus of elasticity was used.

FIG. 35 depicts a result of evaluating the global flatness of the polished surface of the polishing sample 80 after the CMP process. In FIG. 35, the global step (a step (nm) between the convexities 85 and the concavities 86) is shown as the global flatness.

As is understood from FIG. 35, in Example 32, the global flatness 33.9 nanometers is obtained as satisfactory flatness. It can be recognized from this result that a satisfactory planarization characteristic is obtained by the polishing pad having the level “medium” for the modulus of elasticity of the surface layer and having the level “large” for the bulk modulus of elasticity.

As Example 32 is compared with Comparative example 33, the global flatness is satisfactory in Example 32, and the global step in Comparative example 33 is 176 nanometers with an aggravated global flatness. As described above, when the polishing pad having the level “medium” for the bulk modulus of elasticity is used, a satisfactory global flatness cannot be obtained even when the modulus of elasticity of the surface layer is set lower than the bulk modulus of elasticity.

According, it is safe to say from the above result that in the CMP process performed on the polishing sample 80 using the polishing slurry containing the cerium oxide particles and the anionic surfactants, an improvement effect of the planarization characteristic is recognized by using the polishing pad of a high modulus of elasticity (high hardness) having a surface layer of a portion of a low modulus of elasticity with a modulus of elasticity equal to or higher than 50 megapascals and lower than 400 megapascals and by setting the polishing pressure and the rotation number of the polishing pad to low values.

From the results of Example 31, Example 32, and Comparative example 31 to Comparative example 33, it is safe to say that in the CMP process performed on the polishing sample 80 using the polishing slurry containing the cerium oxide particles and the anionic surfactants, an excellent planarization characteristic can be stably obtained by using the polishing pad of a high modulus of elasticity (high hardness) having a surface layer with a depth (thickness) from the surface of the polishing pad within the range of 20 to 100 micrometers and with a modulus of elasticity equal to or higher than 50 megapascals and lower than 400 megapascals and by setting the polishing pressure and the rotation number of the polishing pad to low values.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device manufacturing method comprising:
bringing a substance to be polished made of a silicon oxide film formed on a semiconductor substrate into contact with a polishing pad, in a state that a polishing slurry containing cerium oxide particles and an anionic surfactant is supplied to the polishing pad having a modulus of elasticity within a range of 400 to 600 megapascals arranged above a polishing table, and in a condition that a polishing pressure applied to the substance to be polished is within a range of 50 to 200 hectopascals and that a rotation number of the polishing pad is within a range of 10 to 80 revolutions per minute (rpm); and
sliding the substance to be polished and the polishing pad relatively, thereby chemically and mechanically polishing and planarizing the substance to be polished.

2. The method according to claim 1, wherein the polishing pad is made of a nonfoamed polyurethane resin.

3. The method according to claim 1, wherein the polishing pad has a region to be in contact with the substance to be polished, the region having a depth from a surface within a range of 20 to 100 micrometers and having a modulus of elasticity equal to or higher than 50 megapascals and lower than 400 megapascals.

4. The method according to claim 1, wherein the substance to be polished has a pattern equal to or larger than 2 mm×2 mm having a convexity coverage equal to or larger than 80%.

5. The method according to claim 1, wherein the anionic surfactant has a molecular weight within a range of 500 to 10,000.

6. The method according to claim 1, wherein a concentration of the anionic surfactant in the polishing slurry is within a range of 0.001 wt % (weight percent) to 10 wt %.

7. The method according to claim 1, wherein a primary particle diameter of the cerium oxide particles is within a range of 5 to 100 nanometers.

8. The method according to claim 1, wherein a secondary particle diameter of the cerium oxide particles is within a range of 50 nanometers to 3 micrometers.

9. A semiconductor device manufacturing method comprising:
sliding a substance to be polished made of a silicon oxide film formed on a semiconductor substrate with a polishing pad relatively, in a state that a polishing slurry containing resin particles having a cationic surface functional group, cerium oxide particles, and an anionic surfactant is supplied to the polishing pad arranged above a polishing table, thereby chemically and mechanically polishing and planarizing the substance to be polished.

10. The method according to claim 9, wherein the substance to be polished has a pattern equal to or larger than 2 mm×2 mm having a convexity coverage equal to or larger than 80%.

11. The method according to claim 9, wherein a concentration of the cerium oxide particles in the polishing slurry is within a range of 0.05 wt % to 0.3 wt %.

12. The method according to claim 11, wherein the substance to be polished is polished while supplying a gas to the polishing slurry on the polishing pad.

13. The method according to claim 12, wherein the gas is nitrogen.

14. The method according to claim 9, wherein the polishing pad and the resin particles having the cationic surface functional group are made of organic materials.

15. The method according to claim 14, wherein the polishing pad is made of a polyurethane resin, and the resin particles having the cationic surface functional group are made of polystyrene having an amino group.

16. The method according to claim 9, wherein the anionic surfactant have a molecular weight within a range of 500 to 10,000.

17. The method according to claim 9, wherein a concentration of the resin particles having the cationic surface functional group in the polishing slurry is within a range of 0.001 wt % to 10 wt %.

18. The method according to claim 9, wherein an average particle diameter of the resin particles having the cationic surface functional group is within a range of 10 nanometers to 3 micrometers.

19. The method according to claim 9, wherein a concentration of the anionic surfactant in the polishing slurry is within a range of 0.001 wt % to 10 wt %.

20. A semiconductor device manufacturing method comprising:
bringing a substance to be polished made of a silicon oxide film formed on a semiconductor substrate into contact with a polishing pad, in a state that a polishing slurry containing resin particles having a cationic surface function group, cerium oxide particles, and an anionic surfactant is supplied to the polishing pad having a modulus of elasticity within a range of 400 to 600 megapascals arranged above a polishing table, and in a condition that a polishing pressure applied to the substance to be polished is within a range of 0.50 to 200 hectopascals and that a rotation number of the polishing pad is within a range of 10 to 80 rpm; and
sliding the substance to be polished and the polishing pad relatively, thereby chemically and mechanically polishing and planarizing the substance to be polished.
